(19) United States
(12) Patent Application Publication
(10) Pub. No.: US 2026/0013403 A1
(43) Pub. Date: Jan. 8, 2026

(54) MULTILEVEL WIRING STRUCTURES FOR SUPERCONDUCTING QUANTUM DEVICES

(71) Applicant: International Business Machines Corporation, Armonk, NY (US)

(72) Inventors: Joseph Finley, Rye Brook, NY (US); Santino Carnevale, Stamford, CT (US); John Michael Cotte, New Fairfield, CT (US); Elbert Emin Huang, Mountain View, CA (US); Stephen W. Bedell, Wappingers Falls, NY (US); Joseph Robert Suttle, Chappaqua, NY (US); Ted Thorbeck, Elmsford, NY (US); Matthew Beck, Danbury, CT (US); Marco Turchetti, White Plains, NY (US)

(21) Appl. No.: 18/607,032

(22) Filed: Mar. 15, 2024

(51) Int. Cl. H10N 60/01; G06N 10/40; H10N 60/12; H10N 60/81

(52) U.S. Cl. CPC H10N 60/01; H10N 60/12; H10N 60/815; G06N 10/40

(57) ABSTRACT

A method is provided for fabricating a multilevel wiring structure. A first metallization layer comprising a superconducting metal is formed in a surface of a first substrate. A second substrate is bonded to the first substrate. The second substrate comprises a monocrystalline dielectric material. The second substrate is thinned to form an interlayer dielectric layer which comprises the monocrystalline dielectric material. A second metallization layer comprising a superconducting metal is formed in a surface of the interlayer dielectric layer. The second metallization layer is connected to the first metallization layer by at least one interlayer via in the interlayer dielectric layer.

### BACKGROUND

This disclosure relates generally to superconducting quantum devices for quantum computing and, in particular, to techniques for fabricating low-loss multilevel wiring structures for superconducting quantum devices. A quantum computing system can be implemented using superconducting circuit quantum electrodynamics (cQED) architectures that are constructed using quantum circuit components such as, e.g., superconducting quantum bits and other types of superconducting quantum devices that are controlled using microwave and/or flux bias control signals. In general, superconducting quantum bits (qubits) are electronic circuits which are implemented using components such as superconducting tunnel junctions (e.g., Josephson junctions), superconducting quantum interference devices (SQUIDs), inductors, and/or capacitors, etc., and which behave as quantum mechanical anharmonic (non-linear) oscillators with quantized states, when cooled to cryogenic temperatures.

Various types of quantum information processing algorithms can be implemented using a superconducting quantum processor which comprises multiple superconducting qubits which can be coherently controlled, placed into quantum superposition states, exhibit quantum interference effects, and become entangled with one another, by applying various types of quantum gate operations (e.g., single-qubit gate operations, two-qubit gate operations, etc.) to the superconducting qubits. As quantum processors are scaled with increasing numbers of superconducting qubits and higher integration densities, a low-loss microwave environment is needed to achieve high fidelity quantum gate operations.

In this regard, superconducting qubits and other superconducting quantum devices such as microwave resonators are fabricated on quantum chips comprising low-loss single crystal dielectric substrates. On the other hand, scaling the number of qubits and connectivity requires multilevel wiring structures, which are separately fabricated and connected to the quantum chips on which the qubits and other quantum devices are fabricated, in order to meet signal routing and circuit density requirements.

### SUMMARY

Exemplary embodiments of the disclosure include techniques for fabricating low-loss multilevel wiring structures for superconducting quantum devices and, techniques for integrating superconducting quantum devices (e.g., qubits) within low-loss multilevel wiring structures.

For example, an exemplary embodiment includes a method which comprises forming a multilevel wiring structure by a process which comprises: forming a first metallization layer comprising a superconducting metal in a surface of a first substrate; bonding a second substrate to the first substrate, the second substrate comprising a monocrystalline dielectric material; thinning the second substrate to form an interlayer dielectric layer which comprises the monocrystalline dielectric material; and forming a second metallization layer comprising a superconducting metal in a surface of the interlayer dielectric layer. The second metallization layer is connected to the first metallization layer by at least one interlayer via in the interlayer dielectric layer.

Advantageously, the substrate bonding and substrate thinning techniques enable the formation of low-loss multilevel wiring structures having low-loss interlayer dielectric layers formed of monocrystalline dielectric material. The formation of low-loss multilevel wiring structures having low microwave loss monocrystalline dielectric layers (e.g., monocrystalline silicon) allows various types of superconducting quantum devices and associated circuitry (e.g., readout resonators, coupling busses, etc.) to be integrated within such low-loss multilevel wiring structures to, e.g., achieve quantum chips with high integration density.

Another exemplary embodiment includes a device which comprises a substrate and a multilevel wiring structure disposed on a first surface of the substrate. The multilevel wiring structure comprises a plurality of layers. The plurality of layers comprises a first metallization layer, a second metallization layer, and an interlayer dielectric layer. The first and second metallization layers each comprise a superconducting metal. The interlayer dielectric layer is disposed between the first metallization layer and the second metallization layer. The interlayer dielectric layer comprises a monocrystalline dielectric material.

Another exemplary embodiment includes a device which comprises a multilevel wiring structure, a plurality of superconducting quantum bits, and a plurality of signal transmission lines. The multilevel wiring structure comprises a plurality of metallization layers comprised of superconducting metal, and a plurality of interlayer dielectric layers comprised of monocrystalline dielectric material. Each interlayer dielectric layer comprises interlayer vias comprised of superconducting metal to connect the metallization layers. The plurality of superconducting quantum bits are disposed on at least one interlayer dielectric layer of the multilevel wiring structure. The plurality of signal transmission lines are comprised of portions of the metallization layers and the interlayer vias of the multilevel wiring structure, and are configured to route signals to and from the superconducting quantum bits.

In another exemplary embodiment, as may be combined with the preceding paragraphs, the device further comprises a plurality of coupling buses which are comprised of portions of the metallization layers and the interlayer vias of the multilevel wiring structure. Each coupling bus is configured to couple at least two superconducting quantum bits of the plurality of superconducting quantum bits.

In another exemplary embodiment, as may be combined with the preceding paragraphs, the device further comprises a plurality of readout resonators which are comprised of portions of the metallization layers and the interlayer vias of the multilevel wiring structure. Each readout resonator is coupled to a given superconducting quantum bit of the plurality of superconducting quantum bits.

In another exemplary embodiment, as may be combined with the preceding paragraphs, the device further comprises a second multilevel wiring structure, which is connected to the multilevel wiring structure with solder bump connections. The second multilevel wiring structure comprises a second plurality of metallization layers comprised of superconducting metal, and a second plurality of interlayer dielectric layers comprised of monocrystalline dielectric material, each interlayer dielectric layer of the second plurality of interlayer dielectric layers comprising interlayer vias comprised of superconducting metal to connect metallization layers of the second plurality of metallization layers.

Another exemplary embodiment includes a device which comprises a substrate, an interlayer dielectric layer, and a superconducting quantum bit. The substrate comprises a first metallization layer which is comprised of a superconducting metal disposed in a surface of a first substrate. The interlayer dielectric layer comprises: a first surface disposed on the first metallization layer; a second metallization layer, which is comprised of a superconducting metal, disposed on a second surface of the interlayer dielectric layer, opposite the first surface; and one or more interlayer vias which provide connections between the first metallization layer and the second metallization layer. The superconducting quantum bit comprises at least one Josephson junction and a superconducting capacitor coupled to the at least one Josephson junction. The at least one Josephson junction is disposed on the second surface of the interlayer dielectric layer. The superconducting capacitor comprises patterned features of the first metallization layer and the second metallization layer.

Another exemplary embodiment includes a method which comprises: forming a first metallization layer comprising a superconducting metal in a surface of a first substrate; bonding a second substrate to the first substrate, the second substrate comprising a monocrystalline dielectric material; thinning the second substrate to form an interlayer dielectric layer which comprises the monocrystalline dielectric material; and forming a second metallization layer comprising a superconducting metal in a surface of the interlayer dielectric layer, wherein the second metallization layer is connected to the first metallization layer by one or more interlayer vias in the interlayer dielectric layer; and forming at least one Josephson junction of a superconducting quantum bit on the surface of the interlayer dielectric layer. The first metallization layer and second metallization layer each comprise one or more patterned features of a superconducting capacitor of the superconducting quantum bit, which is coupled to the at least one Josephson junction.

In another exemplary embodiment, as may be combined with the preceding paragraphs, bonding the second substrate to the first substrate comprises performing a substrate-to-metal bonding process to bond the monocrystalline dielectric material of the second substrate to the first metallization layer of the first substrate.

In another exemplary embodiment, as may be combined with the preceding paragraphs, bonding the second substrate to the first substrate comprises performing a substrate-to-substrate bonding process to bond the monocrystalline dielectric material of the second substrate to monocrystalline dielectric material of the first substrate.

In another exemplary embodiment, as may be combined with the preceding paragraphs, bonding the second substrate to the first substrate comprises performing a metal-to-metal bonding process to bond a third metallization layer of superconducting metallic material, which is formed in a surface of the second substrate, to the first metallization layer of superconducting metallic material of the first substrate.

In another exemplary embodiment, as may be combined with the preceding paragraphs, thinning the second substrate to form the interlayer dielectric layer comprises: etching the second substrate down to an etch stop layer; and removing the etch stop layer selective to the monocrystalline dielectric material of the second substrate to form the interlayer dielectric layer which comprises a remaining portion of the second substrate after removing etch stop layer.

In another exemplary embodiment, as may be combined with the preceding paragraphs, the second substrate comprises the at least one interlayer via, and thinning the second substrate to form the interlayer dielectric layer comprises performing a via reveal etch process to etch the second substrate to reveal an end portion of the at least one interlayer via.

Other embodiments will be described in the following detailed description of exemplary embodiments, which is to be read in conjunction with the accompanying figures.

### BRIEF DESCRIPTION OF THE DRAWINGS

FIGS. 1A through 1K schematically illustrate a method for fabricating a multilevel wiring structure of a superconducting quantum device, according to an exemplary embodiment of the disclosure, wherein:

FIGS. 1A and 1B schematically illustrate a multilevel wiring structure at an intermediate stage of fabrication in which a first substrate is processed to form a patterned layer of superconducting metal which is disposed in a surface of the first substrate;

FIGS. 1C and 1D schematically illustrate the multilevel wiring structure at an intermediate stage of fabrication after bonding a second substrate to, the first substrate using a metal-to-metal bonding process;

1E is a schematic cross-sectional side view of the multilevel wiring structure at an intermediate stage of fabrication after performing a wafer thinning process to thin down the second substrate and form a first thinned substrate which serves as an interlayer dielectric layer of the multilevel wiring structure;

FIGS. 1F and 1G schematically illustrate the multilevel wiring structure at an intermediate stage of fabrication after patterning the first thinned substrate to form via and trench openings in the thinned substrate;

FIGS. 1H and 1I schematically illustrate the multilevel wiring structure at an intermediate stage of fabrication after filling the via and trench openings of the first thinned substrate with superconducting metal to form a metallization layer and an interlayer via;

FIG. 1J is a schematic cross-sectional side view of the multilevel wiring structure at an intermediate stage of fabrication after bonding a third substrate to the first thinned substrate; and

FIG. 1K is a schematic cross-sectional side view of the multilevel wiring structure at an intermediate stage of fabrication after performing a wafer thinning process to thin down the third substrate to form a second thinned substrate, and after forming a metallization layer and an interlayer via in the second thinned substrate.

FIGS. 2A through 2F schematically illustrate a method for fabricating a multilevel wiring structure for a superconducting quantum device, according to another exemplary embodiment of the disclosure, wherein:

FIG. 2A is a schematic cross-sectional side view of a multilevel wiring structure at an intermediate stage of fabrication after processing a first substrate to form a patterned layer of superconducting metal in a frontside surface of the first substrate, and after bonding a second substrate to the frontside of the first substrate using a substrate-to-metal bonding process;

FIG. 2B is a schematic cross-sectional side view of the multilevel wiring structure at an intermediate stage of fabrication after performing a wafer thinning process to thin down the second substrate to form a first thinned substrate which serves as an interlayer dielectric layer of the multilevel wiring structure;

FIG. 2C is a schematic cross-sectional side view of the multilevel wiring structure at an intermediate stage of fabrication after patterning the first thinned substrate to form via and trench openings in the first thinned substrate;

FIG. 2D is a schematic cross-sectional side view of the multilevel wiring structure at an intermediate stage of fabrication after filling the via and trench openings of the first thinned substrate with superconducting metal to form a metallization layer and an interlayer via;

FIG. 2E is a schematic cross-sectional side view of the multilevel wiring structure at an intermediate stage of fabrication after bonding a third substrate to the first thinned substrate; and

FIG. 2F is a schematic cross-sectional side view of the multilevel wiring structure at an intermediate stage of fabrication after performing a wafer thinning process to thin down the third substrate to form a second thinned substrate which serves as in interlayer dielectric layer, and after forming another metallization layer and an interlayer via in the second thinned substrate.

FIGS. 3A through 3G schematically illustrate a method for fabricating a multilevel wiring structure for a superconducting quantum device, according to another exemplary embodiment of the disclosure, wherein:

FIGS. 3A and 3B schematically illustrate a multilevel wiring structure at an intermediate stage of fabrication in which a first substrate is processed to form a patterned layer of superconducting metal which is disposed in a frontside surface of the first substrate;

FIG. 3C is a schematic cross-sectional side view of a multilevel wiring structure at an intermediate stage of fabrication after bonding a second substrate to the first substrate using a substrate-to-substrate bonding process;

FIG. 3D is a schematic cross-sectional side view of the multilevel wiring structure at an intermediate stage of fabrication after performing a wafer thinning process to thin down the second substrate to form a first thinned substrate which serves as an interlayer dielectric layer, and after patterning the first thinned substrate to form via and trench openings in the first thinned substrate;

FIG. 3E is a schematic cross-sectional side view of the multilevel wiring structure at an intermediate stage of fabrication after filling the via and trench openings in the first thinned substrate with a superconducting metal to form a metallization layer and an interlayer via;

FIG. 3F is a schematic cross-sectional side view of the multilevel wiring structure at an intermediate stage of fabrication after bonding a third substrate to the first thinned substrate; and

FIG. 3G is a schematic cross-sectional side view of the multilevel wiring structure at an intermediate stage of fabrication after performing a wafer thinning process to thin down the third substrate to form a second thinned substrate which serves as in interlayer dielectric layer, and after forming another metallization layer and an interlayer via in the second thinned substrate.

FIGS. 4A through 4D schematically illustrate a method for fabricating a multilevel wiring structure for a superconducting quantum device, according to another exemplary embodiment of the disclosure, wherein:

FIG. 4A is a schematic cross-sectional side view of a multilevel wiring structure at an intermediate stage of fabrication after bonding a first substrate to a second substrate by metal-to-metal bonding of metallization layers of the first and second substrates;

FIG. 4B is a schematic cross-sectional side view of the multilevel wiring structure at an intermediate stage of fabrication after performing a wafer thinning process to thin down the second substrate to a level which reveals an end of an embedded via, and thereby form a first thinned substrate which serves as an interlayer dielectric layer of the multilevel wiring structure;

FIG. 4C is a schematic cross-sectional side view of the multilevel wiring structure at an intermediate stage of fabrication after forming a patterned metallization layer in the surface of the first thinned substrate in contact with the exposed end of the interlayer via; and

FIG. 4D is a schematic cross-sectional side view of the multilevel wiring structure at an intermediate stage of fabrication after bonding a third substrate to the first thinned substrate.

FIGS. 5A through 5D schematically illustrate a method for fabricating a multilevel wiring structure for a superconducting quantum device, according to another exemplary embodiment of the disclosure, wherein:

FIG. 5A is a schematic cross-sectional side view of a multilevel wiring structure at an intermediate stage of fabrication after processing a first substrate to form a patterned layer of superconducting metal in a surface of the first substrate, and after bonding a second substrate, which has an etch stop layer, to the first substrate using a substrate-to-metal bonding process;

FIG. 5B is a schematic cross-sectional side view of the multilevel wiring structure at an intermediate stage of fabrication after etching the second substrate down to the etch stop layer;

FIG. 5C is a schematic cross-sectional side view of the multilevel wiring structure at an intermediate stage of fabrication after removing the etch stop layer to provide a first thinned substrate which serves as an interlayer dielectric layer of the multilevel wiring structure; and

FIG. 5D is a schematic cross-sectional side view of the multilevel wiring structure at an intermediate stage of fabrication after forming a metallization layer and interlayer via in the first thinned substrate, and after bonding a third substrate to the first thinned substrate.

FIG. 6 schematically illustrates a quantum device which comprises a multilevel wiring structure with integrated superconducting qubits, according to an exemplary embodiment of the disclosure.

FIG. 7 schematically illustrates a quantum device which comprises a multilevel wiring structure with integrated superconducting qubits, according to another exemplary embodiment of the disclosure.

FIG. 8 schematically illustrates a quantum device which comprises a multilevel wiring structure with integrated superconducting qubits, according to another exemplary embodiment of the disclosure.

FIG. 9 is a schematic cross-sectional side view of a quantum device which comprises a multilevel superconducting qubit structure, according to an exemplary embodiment of the disclosure.

FIG. 10 is a schematic cross-sectional side view of a quantum device which comprises a multilevel superconducting qubit structure, according to another exemplary embodiment of the disclosure.

FIG. 11 is a schematic cross-sectional side view of a quantum device which comprises a multilevel superconducting qubit structure, according to another exemplary embodiment of the disclosure.

FIG. 12 illustrates a flow diagram of a process for fabricating a multilevel wiring structure of a superconducting quantum device, according to an exemplary embodiment of the disclosure.

FIG. 13 schematically illustrates a quantum computing system which comprises a quantum processor which comprises a multilevel wiring structure having integrated superconducting qubits, according to an exemplary embodiment of the disclosure.

### DETAILED DESCRIPTION

Exemplary embodiments of the disclosure will now be described in further detail with regard to techniques for fabricating low-loss multilevel wiring structures for superconducting quantum devices, as well as techniques for integrating superconducting quantum devices (e.g., qubits) within low-loss multilevel wiring structures. As explained in further detail below, exemplary wafer bonding and wafer thinning techniques are utilized to form low-loss monocrystalline dielectric layers (e.g., monocrystalline silicon) and thereby construct low microwave loss multilevel wiring structures. The wafer bonding and wafer thinning techniques are implemented to form multilevel wiring structures having low-loss interlayer dielectric layers formed of monocrystalline dielectric material. The formation of low-loss multilevel wiring structures having low microwave loss monocrystalline dielectric layers (e.g., monocrystalline silicon) allows various types of superconducting quantum devices and circuitry to be integrated within such low-loss multilevel wiring structures. The exemplary low-loss multilevel wiring structures and associated low-loss multilevel wiring fabrication methods provide advantages over conventional multilevel wiring structures which are fabricated using inherently lossy amorphous interlayer dielectrics, which limits the use of multilevel wiring structures to provide a low-loss microwave environment for superconducting devices and circuitry, and which prevents the integration of quantum devices, which require low microwave loss to minimize errors, within a lossy multilevel wiring structure.

It is to be understood that the various features shown in the accompanying drawings are schematic illustrations that are not drawn to scale. Moreover, the same or similar reference numbers are used throughout the drawings to denote the same or similar features, elements, or structures, and thus, a detailed explanation of the same or similar features, elements, or structures will not be repeated for each of the drawings. To provide spatial context to the different structural orientations of the semiconductor structures shown in the drawings, XYZ Cartesian coordinates are shown in the drawings. The terms “vertical” or “vertical direction” or “vertical height” as used herein denote a Z-direction of the Cartesian coordinates shown in the drawings, and the terms “horizontal,” “horizontal direction,” “lateral,” or “lateral direction” as used herein denote an X-direction and/or a Y-direction of the Cartesian coordinates shown in the drawings.

In addition, for ease of explanation, one or more layers, structures, and regions of a type commonly used to form superconducting quantum devices and circuitry may not be explicitly shown in a given drawing. This does not imply that any layers, structures, and regions not explicitly shown are omitted from the actual superconducting quantum devices and circuits. It is to be further understood that references herein to formation of one layer or structure “on” or “over” another layer or structure are intended to be broadly construed, and should not be interpreted as precluding the presence of one or more intervening layers or structures.

Furthermore, it is to be understood that the embodiments discussed herein are not limited to the particular materials, features, and processing steps shown and described herein. In particular, with respect to semiconductor processing steps, it is to be emphasized that the descriptions provided herein are not intended to encompass all of the processing steps that may be required to form a functional superconducting quantum devices or quantum circuits. Rather, certain processing steps that are commonly used in forming superconducting quantum devices or quantum circuits, such as, for example, metal deposition, wet cleaning and annealing steps, are purposefully not described herein for economy of description.

Further, the term “exemplary” as used herein means “serving as an example, instance, or illustration.” Any embodiment or design described herein as “exemplary” is not to be construed as preferred or advantageous over other embodiments or designs. The terms “about” or “substantially” as used herein with regard to thicknesses, widths, percentages, ranges, etc., are meant to denote being close or approximate to, but not exactly. For example, the term “about” or “substantially” as used herein implies that a small margin of error is present, such as 1% or less than the stated amount.

Moreover, the phrase “configured to” as used in conjunction with a circuit, structure, element, component, or the like, performing one or more functions or otherwise providing some functionality, is intended to encompass embodiments wherein the circuit, structure, element, component, or the like, is implemented in hardware, software, and/or combinations thereof, and in implementations that comprise hardware, wherein the hardware may comprise quantum circuit elements (e.g., quantum bits, tunable couplers, etc.), discrete circuit elements (e.g., transistors, inverters, etc.), programmable elements (e.g., application specific integrated circuit (ASIC) chips, field-programmable gate array (FPGA) chips, etc.), processing devices (e.g., central processing units (CPUs), graphics processing units (GPUs), etc.), one or more integrated circuits, and/or combinations thereof. Thus, by way of example only, when a circuit, structure, element, component, etc., is defined to be configured to provide a specific functionality, it is intended to cover, but not be limited to, embodiments where the circuit, structure, element, component, etc., is comprised of elements, processing devices, and/or integrated circuits that enable it to perform the specific functionality when in an operational state (e.g., connected or otherwise deployed in a system, powered on, receiving an input, and/or producing an output), as well as cover embodiments when the circuit, structure, element, component, etc., is in a non-operational state (e.g., not connected nor otherwise deployed in a system, not powered on, not receiving an input, and/or not producing an output) or in a partial operational state.

In addition, the term “quantum chip” as used herein refers to a die (e.g., semiconductor die) which comprises a superconducting electronic integrated circuit (or quantum circuit) comprising various superconducting components such as qubits, tunable couplers, ground planes, signal coplanar waveguides, and resonators, etc. A plurality of dies having the same and/or different configurations of superconducting electronic integrated circuits, can be fabricated on a wafer (e.g., semiconductor wafer), wherein the individual dies can be diced (cut) from the wafer using a die singulation process to provide singulated dies which can be packaged together to construct a modular quantum processor architecture. Moreover, as explained in further detail below, a “quantum chip” can be fabricated to have a superconducting quantum circuit with multiple superconducting qubits, together with an integrated low-loss multilevel wiring structure having transmission lines (e.g., control lines, readout resonators, etc.) to transmit signals to and from the superconducting qubits, as well as coupling buses (e.g., transmission line resonators) to couple qubits together to facilitate, e.g., two-qubit gate operations.

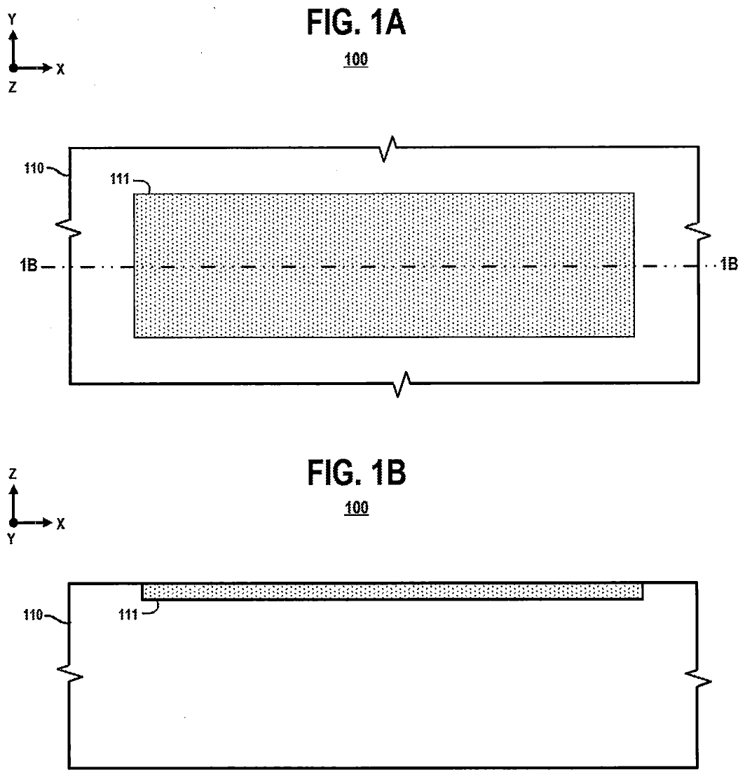

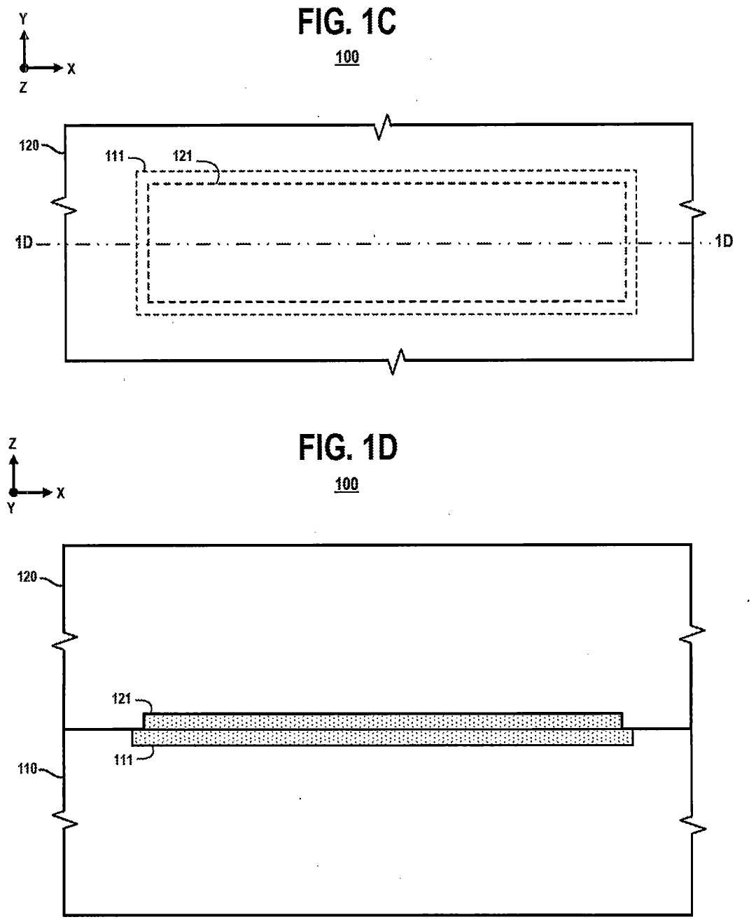

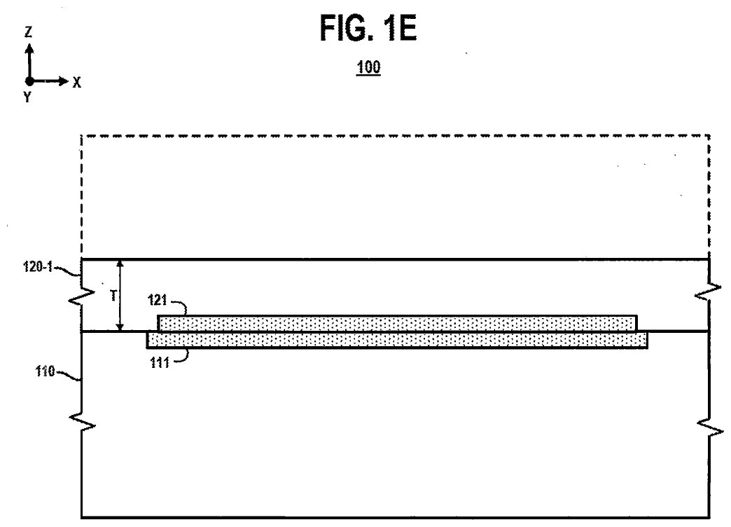

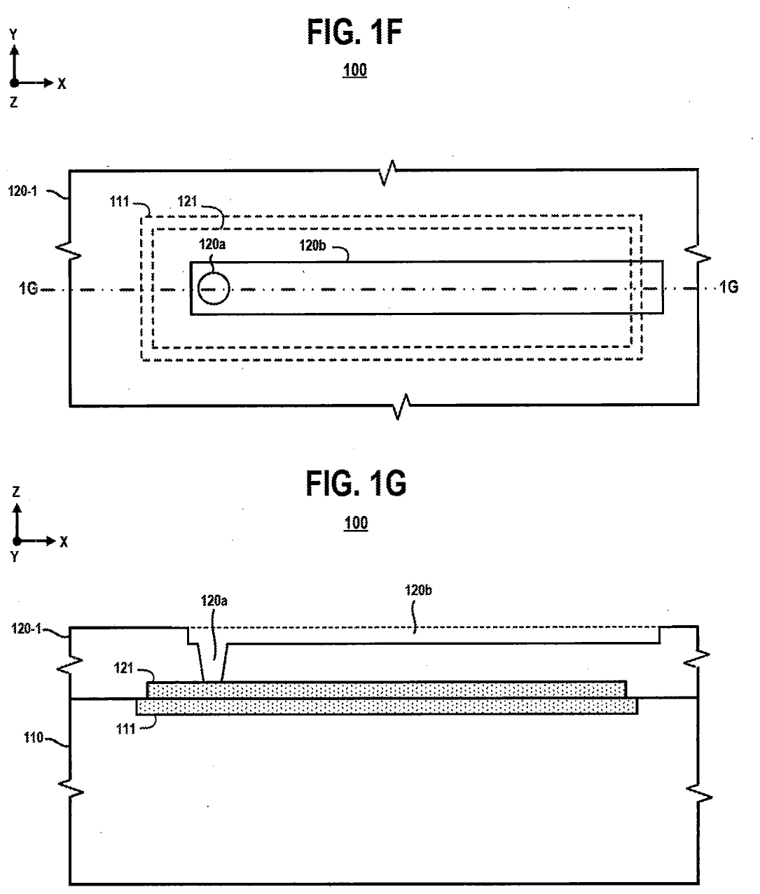

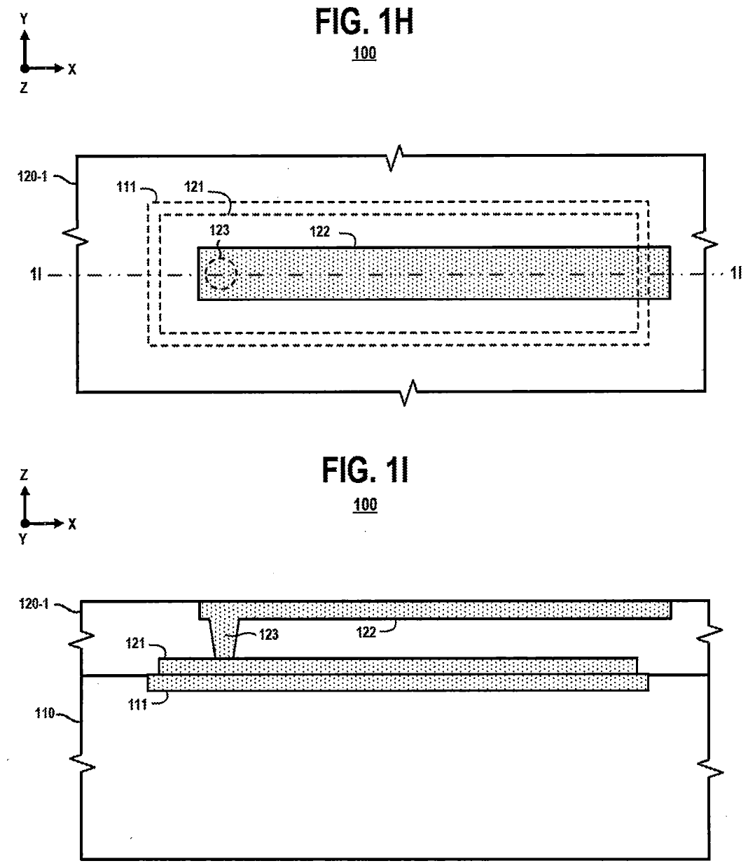

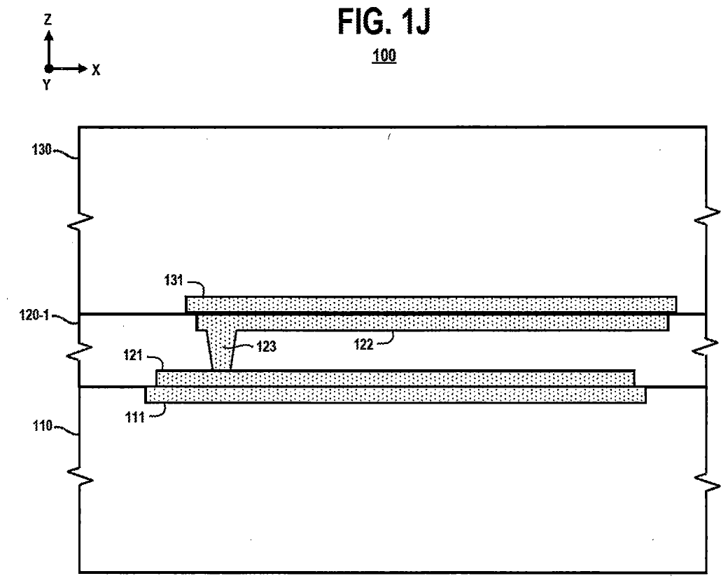

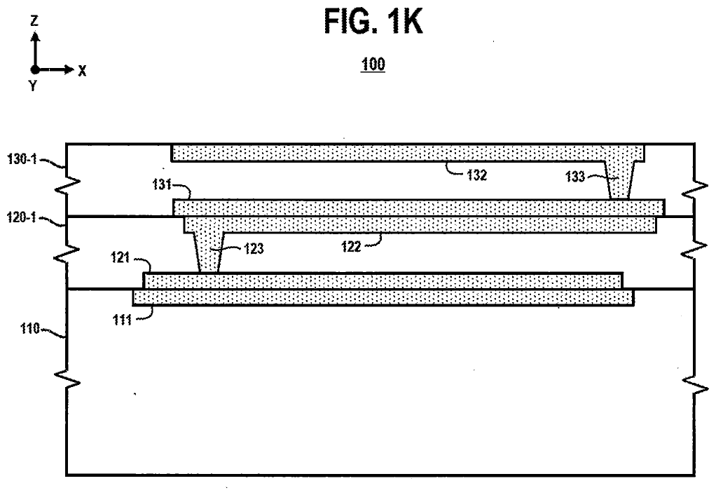

FIGS. 1A through 1K schematically illustrate a method for fabricating a multilevel wiring structure of a superconducting quantum device, according to an exemplary embodiment of the disclosure. In particular, FIGS. 1A through 1K schematically illustrate a method for fabricating a multilevel wiring structure which comprises (i) utilizing metal-to-metal bonding techniques to bond substrates that are formed of low-loss dielectric substrate material (e.g., monocrystalline silicon), and (ii) utilizing substrate thinning techniques to thin down the low-loss substrates to form low-loss interlayer dielectric layers of the multilevel wiring structure. To begin, FIGS. 1A and 1B schematically illustrate a multilevel wiring structure 100 at an intermediate stage of fabrication in which a first substrate 110 (or support substrate 110) is processed to form a patterned layer of superconducting metal 111 (or metallization layer 111) which is disposed in a surface of the first substrate 110, wherein FIG. 1A is a schematic top plan view of the multilevel wiring structure 100, and FIG. 1B is a schematic cross-sectional side view of the multilevel wiring structure 100 along line 1B-1B in FIG. 1A.

In the exemplary embodiment, the first substrate 110 serves as a support substrate (alternatively referred to as handle substrate) on which multiple metallization and interlayer dielectric layers are formed. In some embodiments, the first substrate 110 comprises a semiconductor substrate (e.g., semiconductor wafer) that is formed of monocrystalline (single crystal) semiconductor material such as monocrystalline silicon. In other embodiments, the first substrate 110 can be formed with any suitable low-loss (high resistivity) dielectric material (e.g., resistivity of greater than 500 ohms-centimeter (0-cm)) such as single crystal aluminum oxide (Al₂O₃), single crystal magnesium oxide (MgO), single crystal silicon oxide (SiO₂), and other types of single crystal dielectric materials which are suitable for the given application.

The superconducting metal 111 can be formed of type of superconducting material which is suitable for the given application. For example, the superconducting metal 111 may be aluminum (Al), niobium (Nb), tantalum (Ta), titanium (Ti), tungsten (W), tin (Sn), molybdenum (Mo), or nitrides of the same, a combination thereof, and/or the like. A superconducting metal is a metal or metallic material which exhibits superconducting properties (e.g., no electrical resistance, expels magnetic fields when in a superconducting state) at or below a superconducting critical temperature.

As schematically illustrated in FIG. 1B, the layer of superconducting metal 111 is embedded in the frontside surface of the first substrate 110 to achieve a planar surface and thereby facilitate substrate-to-substrate bonding. For example, in some embodiments, the layer of superconducting metal 111 is formed using a damascene process which comprises: (i) patterning the surface of first substrate 110 to form one or more trenches in the substrate surface, which define the desired pattern of the superconducting metal 111; (ii) depositing a layer of superconducting metal to overfill the open trenches in the substrate; and (iii) removing the excess (overburden) superconducting metal by performing, e.g., a chemical-mechanical planarization (CMP) process to planarize down to the upper surface of the first substrate 110, and leaving the superconducting metal within the trenches to thereby form the metallization layer 111. The superconducting metal can be deposited using known techniques including, but not limited to, physical vapor deposition (PVD) (e.g., evaporation, sputtering), electroplating, or chemical vapor deposition (CVD), etc.

Next, FIGS. 1C and 1D schematically illustrate the multilevel wiring structure 100 at an intermediate stage of fabrication after bonding a second substrate 120 to the first substrate 110, wherein FIG. 1C is a schematic top plan view of the multilevel wiring structure 100, and FIG. 1D is a schematic cross-sectional side view of the multilevel wiring structure 100 along line 1D-1D in FIG. 1C. The second substrate 120 comprises a patterned layer of superconducting metal 121 (or metallization layer 121) which is disposed in a surface of the second substrate 120. In some embodiments, the second substrate 120 is formed of the same or similar low-loss material as the first substrate 110, and the metallization layer 121 is formed of the same superconducting metal (and same fabrication process) as the metallization layer 111.

As schematically illustrated in FIGS. 1C and 1D, the metallization layers 111 and 121 have the same or similar footprint area, and are configured to enable metal-to-metal bonding of the second substrate 120 to the first substrate 110. The metal-to-metal bonding can be implemented using any suitable bonding process. For example, in some embodiments, a low-temperature UHV (ultrahigh vacuum) eutectic bonding process can be implemented which is configured to enable in situ surface preparation (to remove oxide) and metal-to-metal bonding at a low temperature, e.g., in a range of about 100° C. to 400° C., depending on the type of superconducting metal. As schematically illustrated in FIGS. 1C and 1D, the metal-to-metal bonding of the metallization layers 111 and 121 results in bonding the first and second substrates 110 and 120. In an exemplary embodiment, the bonded metallization layers 111 and 121 can collectively form a ground plane of the multilevel wiring structure 100.

Next, FIG. 1E is a schematic cross-sectional side view of the multilevel wiring structure 100 at an intermediate stage of fabrication after performing a wafer thinning process to thin down the second substrate 120 to form a thinned substrate 120-1 (or first thinned substrate 120-1) which serves as an interlayer dielectric layer of the multilevel wiring structure 100. In particular, as schematically shown in FIG. 1E, a portion of the backside of the second substrate 120 is removed (as indicated by the dashed-line outline) to generate the thinned substrate 120-1 with a desired thickness T, which forms an interlayer dielectric layer of the multilevel wiring structure 100. In some embodiments, the backside of the second substrate 120 can be removed using known techniques including, but not limited to, backside wafer grinding, CMP, or a combination of wafer grinding and CMP, etc. In some embodiments, the second substrate 120 can have an initial thickness of 700-800 microns or 300 microns, wherein the backside grinding is performed to thin down the second substrate 120 to a desired thickness of 10s of microns or less. For example, in some embodiments, the thickness T of the thinned substrate 120-1 (or interlayer dielectric layer) is in a range of about 2 microns to about 20 microns.

A next stage of the fabrication process includes forming a next metallization level of the multilevel wiring structure 100. For example, FIGS. 1F and 1G schematically illustrate the multilevel wiring structure 100 at an intermediate stage of fabrication after patterning the thinned substrate 120-1 to form via and trench openings in the thinned substrate 120-1. FIG. 1F is a schematic top plan view of the multilevel wiring structure 100, and FIG. 1G is a schematic cross-sectional side view of the multilevel wiring structure 100 along line 1G-1G in FIG. 1F. As shown, the thinned substrate 120-1 is patterned to form, e.g., a via opening 120a and a trench opening 120b. In some embodiments, the thinned substrate 120-1 is patterned using standard photolithography techniques for performing a dual damascene process in which the via opening 120a and the trench opening 120b are concurrently formed, followed by deposition of a superconducting metal to form a patterned metallization layer and interlayer via, such as shown in FIGS. 1H and 1I.

In particular, FIGS. 1H and 1I schematically illustrate the multilevel wiring structure 100 at an intermediate stage of fabrication after filling the via and trench openings 120a and 120b of the thinned substrate 120-1 with a superconducting metal to form a metallization layer 122 and an interlayer via 123 which connects the metallization layer 122 to the metallization layer 121. FIG. 1H is a schematic top plan view of the multilevel wiring structure 100, and FIG. 1I is a schematic cross-sectional side view of the multilevel wiring structure 100 along line 1I-1I in FIG. 1H. The metallization layer 122 and the interlayer via 123 can be formed by depositing a superconducting metal (e.g., Al, Nb, Ta, Ti, W, Sn, Mo, or nitrides thereof, etc.) on the thinned substrate 120-1 to overfill the via and trench openings 120a and 120b with the superconducting metal, and then removing the excess (overburden) superconducting metal by performing, e.g., a CMP process to planarize down to the upper surface of the thinned substrate 120-1 to form the metallization layer 122 and the interlayer via 123.

Next, FIG. 1J is a schematic cross-sectional side view of the multilevel wiring structure 100 at an intermediate stage of fabrication after bonding a third substrate 130 to the thinned substrate 120-1. The third substrate 130 comprises a patterned layer of superconducting metal 131 (or metallization layer 131) which is disposed in a surface of the third substrate 130. In some embodiments, the third substrate 130 is formed of the same or similar low-loss material as the first and second substrates 110 and 120, and the metallization layer 131 is formed of the same superconducting metal (and same fabrication process) as the metallization layers 111, 121, and 122, and the interlayer via 123. The bonding process is performed by metal-to-metal bonding the metallization layer 131 of the third substrate 130 to the metallization layer 122 of the thinned substrate 120-1 using any suitable bonding process such as a low-temperature UHV eutectic bonding process.

Next, FIG. 1K is a schematic cross-sectional side view of the multilevel wiring structure 100 at an intermediate stage of fabrication after performing a wafer thinning process to thin down the third substrate 130 to form a thinned substrate 130-1 (which serves as in interlayer dielectric layer), and after forming another metallization layer 132 and an interlayer via 133 which connects the metallization layer 132 to the metallization layer 131. The wafer thinning process and metallization formation process are performed using the same or similar techniques as discussed above. The same process steps (e.g., FIGS. 1J and 1K) can be repeated one or more times to create additional wiring levels, as needed. It is to be noted that while the exemplary fabrication process of FIGS. 1A through 1K is discussed in the context of utilizing metal-to-metal wafer bonding, the process flow is compatible with a hybrid bonding process which includes both metal-to-metal bonding and substrate-to-substrate bonding to bond wafers together.

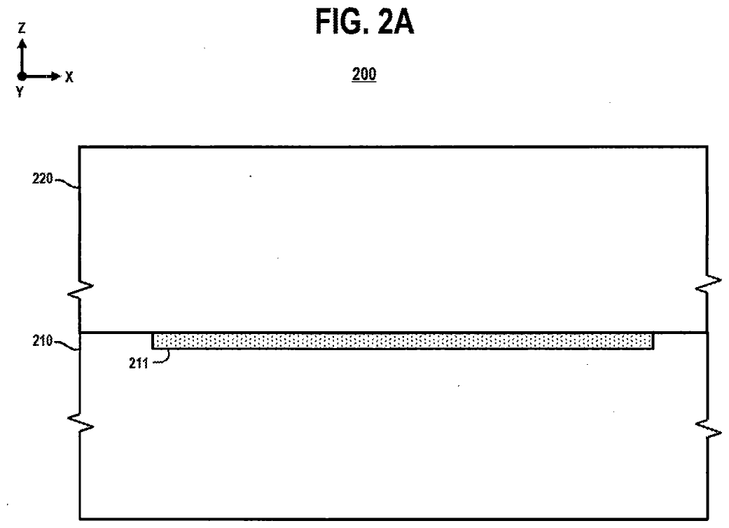

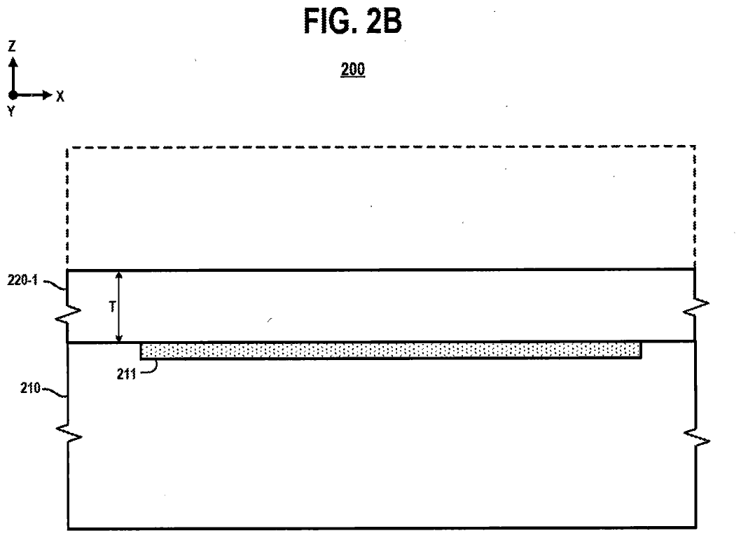

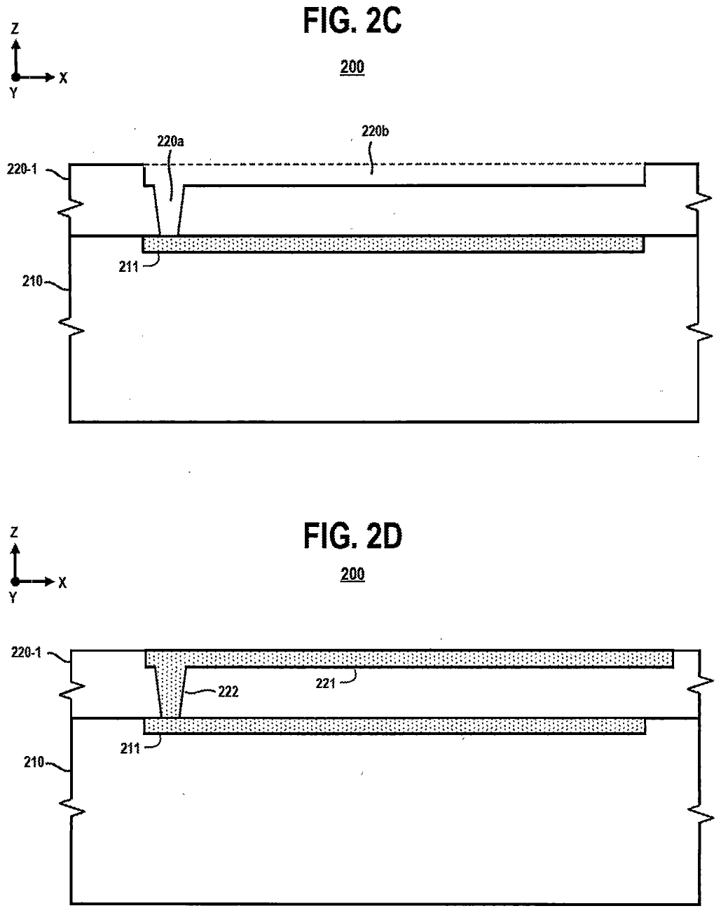

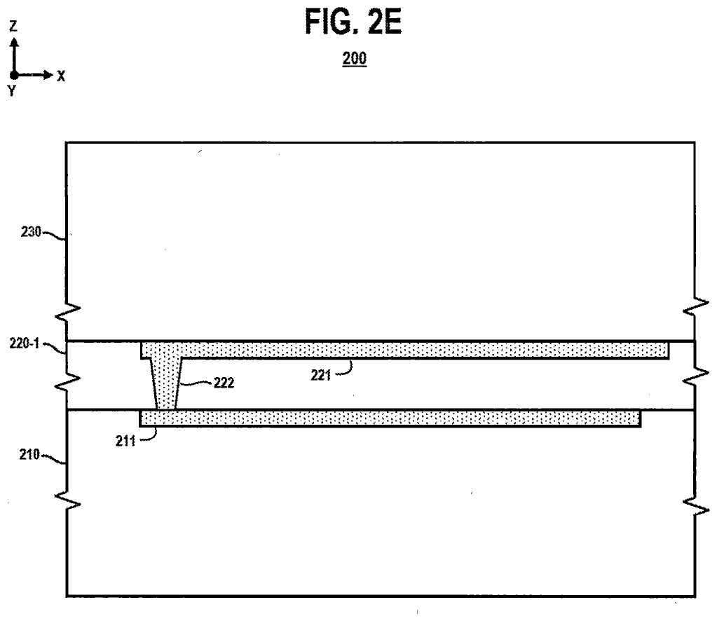

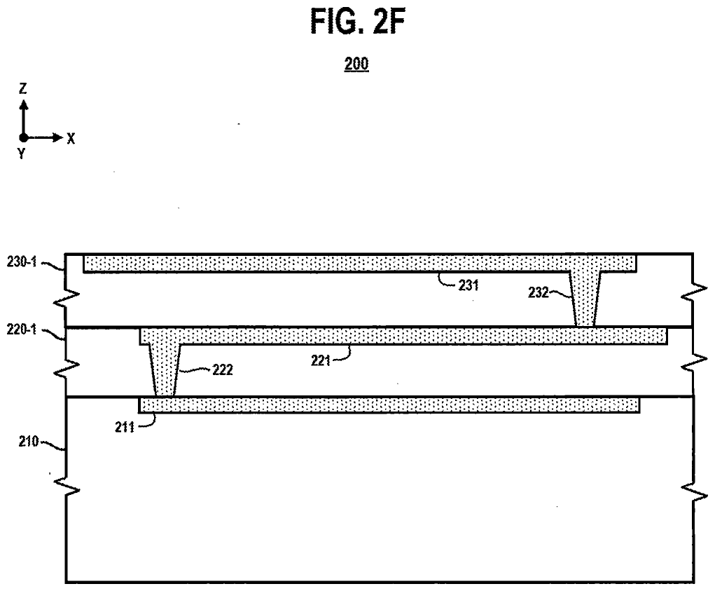

FIGS. 2A through 2F schematically illustrate a method for fabricating a multilevel wiring structure for a superconducting quantum device, according to another exemplary embodiment of the disclosure. In particular, FIGS. 2A through 2F schematically illustrate a method for fabricating a multilevel wiring structure which comprises (i) utilizing substrate-to-metal bonding techniques to bond substrates that are formed of low-loss substrate material (e.g., monocrystalline silicon), and (ii) utilizing substrate thinning techniques to thin down the low-loss substrates to form low-loss interlayer dielectric layers of the multilevel wiring structure.

To begin, FIG. 2A is a schematic cross-sectional side view of a multilevel wiring structure 200 at an intermediate stage of fabrication after processing a first substrate 210 (or support substrate 210) to form a patterned layer of superconducting metal 211 (or metallization layer 211) in a frontside surface of the first substrate 210, and after bonding a second substrate 220 to the frontside of the first substrate 210 using a substrate-to-metal bonding process. The first and second substrates 210 and 220 are formed of suitable low-loss substrate materials (e.g., monocrystalline silicon) as described above, and the metallization layer 211 can be formed of any suitable superconducting metal as described above.

As schematically illustrated in FIG. 2A, the metallization layer 211 is disposed in a surface of the first substrate 210 to provide a planar surface to interface and bond to a planar surface of the second substrate 220. The second substrate 220 is bonded to the first substrate 210 using a substrate-to-metal fusing bonding process in which the surface of the second substrate 220 is bonded to the metallization layer 211 of the first substrate 210. The substrate-to-metal fusing bonding process is performed using any state-of-the-art fusion bonding process which is suitable to fusion bond the material of the second substrate 220 with the material of the metallization layer 211, the details of which are known to those of ordinary skill in the art.

Next, FIG. 2B is a schematic cross-sectional side view of the multilevel wiring structure 200 at an intermediate stage of fabrication after performing a wafer thinning process to thin down the second substrate 220 to form a thinned substrate 220-1 which serves as an interlayer dielectric layer of the multilevel wiring structure 100. In particular, as schematically shown in FIG. 2B, a portion of the backside of the second substrate 220 is removed (as indicated by the dashed-line outline) to generate the thinned substrate 220-1 with a desired thickness T. As noted above, the wafer thinning process can be performed using known techniques including, but not limited to, backside wafer grinding, CMP, or a combination thereof, etc.

A next stage of the fabrication process includes forming a metallization layer on the surface of the thinned substrate 220-1 and interlayer vias that connect the metallization layer to the metallization layer 211 of the first substrate 210. For example, FIG. 2C is a schematic cross-sectional side view of the multilevel wiring structure 200 at an intermediate stage of fabrication after patterning the thinned substrate 220-1 to form a via and trench openings in the thinned substrate 220-1. In particular, as shown in FIG. 2C, the thinned substrate 220-1 is patterned to form, e.g., a via opening 220a and a trench opening 220b. In some embodiments, as noted above, the thinned substrate 220-1 is patterned using standard photolithography techniques for performing a dual damascene process in which the via opening 220a and the trench opening 220b are concurrently formed, followed by deposition of a superconducting metal to form a patterned metallization layer and interlayer via, such as shown in FIG. 2D.

In particular, FIG. 2D is a schematic cross-sectional side view of the multilevel wiring structure 200 at an intermediate stage of fabrication after filling the via and trench openings 220a and 220b of the thinned substrate 220-1 with a superconducting metal to form a metallization layer 221 and an interlayer via 223 which connects the metallization layer 221 to the metallization layer 211 of the first substrate 210. The metallization layer 221 and the interlayer via 222 can be formed by depositing a superconducting metal (e.g., Al, Nb, Ta, Ti, W, Sn, Mo, or nitrides thereof, etc.) on the thinned substrate 220-1 to overfill the via and trench openings 220a and 220b with the superconducting metal, and then removing the excess (overburden) superconducting metal by performing, e.g., a CMP process to planarize down to the upper surface of the thinned substrate 220-1 to form the metallization layer 221 and the interlayer via 222.

Next, FIG. 2E is a schematic cross-sectional side view of the multilevel wiring structure 200 at an intermediate stage of fabrication after bonding a third substrate 230 to the thinned substrate 220-1. In some embodiments, the third substrate 230 is formed of the same or similar low-loss material as the first and second substrates 210 and 220. The third substrate 230 is bonded to the thinned substrate 220-1 using a substrate-to-metal fusing bonding process in which the surface of the third substrate 230 is bonded to the metallization layer 221 of the thinned substrate 220-1. As noted above, the substrate-to-metal fusing bonding process is performed using any state-of-the-art fusion bonding process which is suitable to fusion bond the material of the third substrate 230 with the material of the metallization layer 221, the details of which are known to those of ordinary skill in the art.

Next, FIG. 2F is a schematic cross-sectional side view of the multilevel wiring structure 200 at an intermediate stage of fabrication after performing a wafer thinning process to thin down the third substrate 230 to form a thinned substrate 230-1 (which serves as in interlayer dielectric layer), and after forming another metallization layer 231 and an interlayer via 232 which connects the metallization layer 231 to the underlying metallization layer 221 of the thinned substrate 220-1. The wafer thinning process and metallization formation process are performed using the same or similar techniques as discussed above. The same process steps (e.g., FIGS. 2E and 2F) can be repeated one or more times to create additional wiring levels as needed. It is to be noted that while the exemplary fabrication process of FIGS. 2A through 2F is discussed in the context of utilizing substrate-to-metal wafer bonding, the process flow is compatible with a hybrid bonding process which includes both metal-to-metal bonding and substrate-to-substrate bonding to bond wafers together.

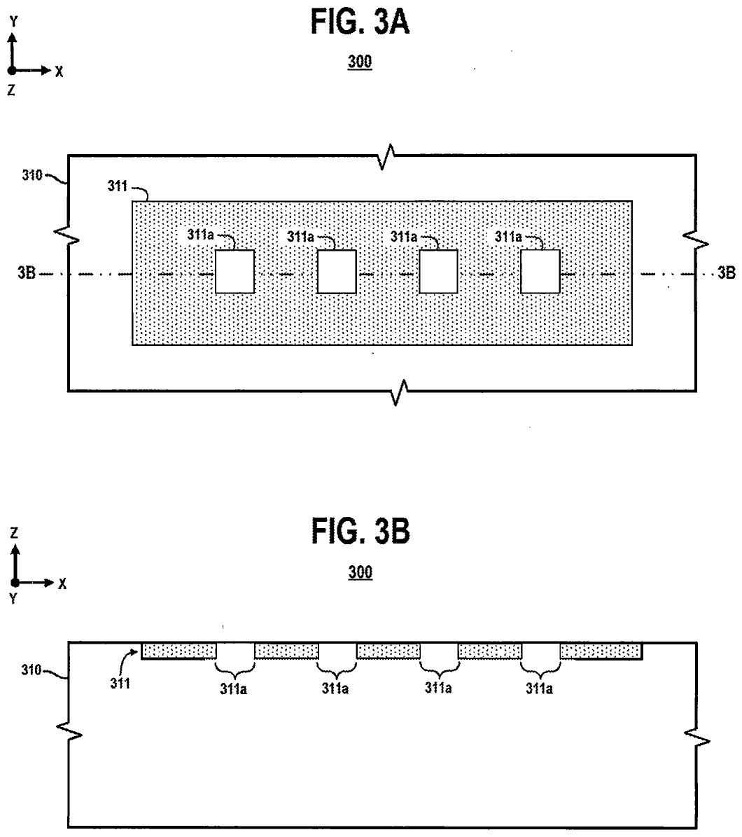

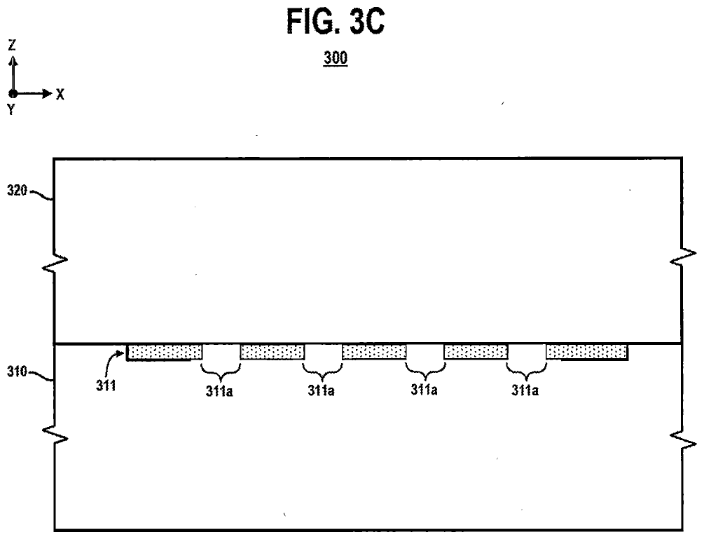

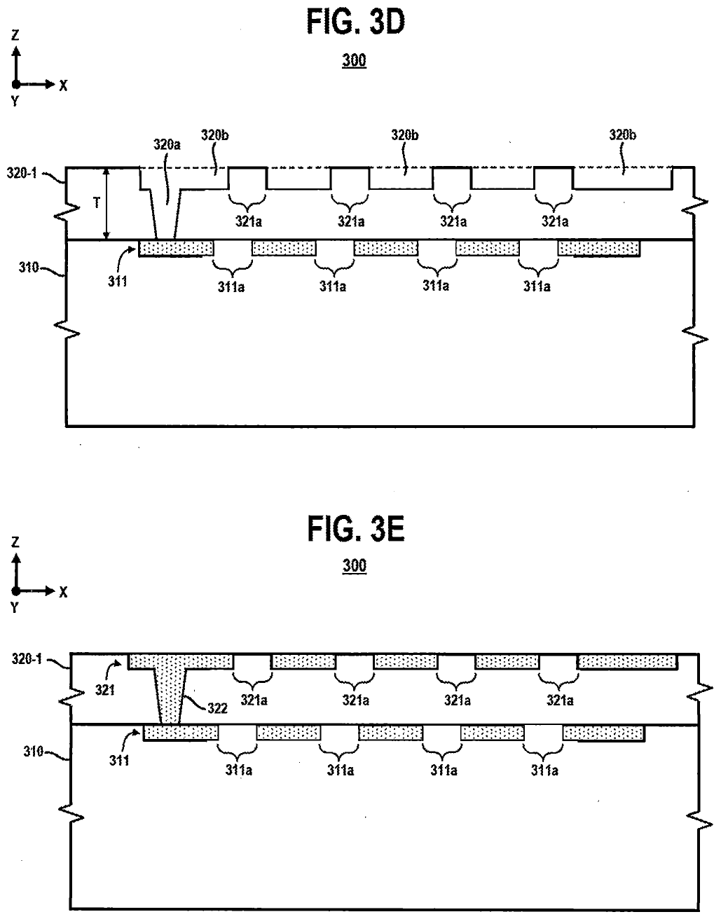

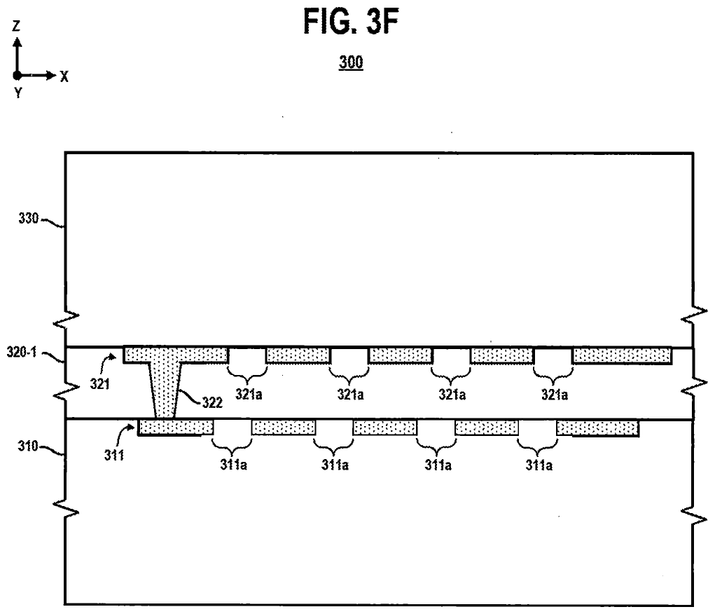

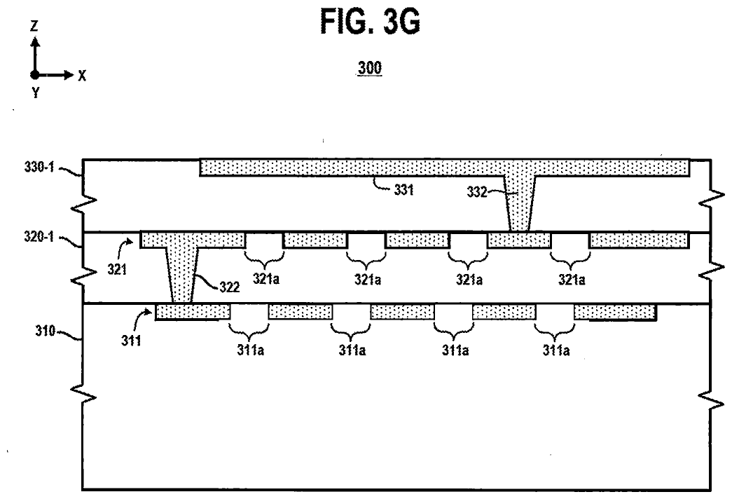

FIGS. 3A through 3G schematically illustrate a method for fabricating a multilevel wiring structure for a superconducting quantum device, according to another exemplary embodiment of the disclosure. In particular, FIGS. 3A through 3G schematically illustrate a method for fabricating a multilevel wiring structure which comprises (i) utilizing substrate-to-substrate bonding techniques to bond substrates that are formed of low-loss substrate material (e.g., monocrystalline silicon), and (ii) utilizing substrate thinning techniques to thin down the low-loss substrates to form low-loss interlayer dielectric layers of the multilevel wiring structure.

To begin, FIGS. 3A and 3B schematically illustrate a multilevel wiring structure 300 at an intermediate stage of fabrication in which a first substrate 310 (or support substrate 310) is processed to form a patterned layer of superconducting metal 311 (or metallization layer 311) which is disposed in a frontside surface of the first substrate 310. FIG. 3A is a schematic top plan view of the multilevel wiring structure 300, and FIG. 3B is a schematic cross-sectional side view of the multilevel wiring structure 300 along line 3B-3B in FIG. 3A. As schematically illustrated in FIG. 3B, the metallization layer 311 is disposed in a surface of the first substrate 310 to provide a planar surface to interface and bond to a planar surface of another substrate (FIG. 3C). The first substrate 310 is formed of a suitable low-loss substrate material (e.g., monocrystalline silicon) as described above, and the metallization layer 411 is formed of a suitable superconducting metal as described above.

As schematically shown in FIGS. 3A and 3B, the metallization layer 311 is formed to have a plurality of discontinuities 311a which expose portions of the surface of the first substrate 310 to facilitate substrate-to-substrate bonding. Indeed, the formation of the discontinuities 311a in the metallization layer 311 allows sufficient substrate area to be exposed within the footprint area of the metallization layer 311 to ensure a good substrate-to-substrate bond in instances where the metallization layer 311 has a relatively large area, e.g., where the metallization layer 311 comprises a large-area ground plane in the metallization level.

Next, FIG. 3C is a schematic cross-sectional side view of a multilevel wiring structure 300 at an intermediate stage of fabrication after bonding a second substrate 320 to the first substrate 310 using a substrate-to-substrate bonding process. In an exemplary embodiment, the second substrate 320 is formed of the same or similar low-loss substrate material (e.g., monocrystalline silicon) as the first substrate 310. The second substrate 320 is bonded to the first substrate 310 using a substrate-to-substrate direct bonding process in which the surface of the second substrate 320 is bonded to exposed surfaces of the first substrate 310. The substrate-to-substrate bonding process is performed using any state-of-the-art direct bonding or fusion bonding process which is suitable to bond the material of the second substrate 320 with the material of the first substrate 310, the details of which are known to those of ordinary skill in the art.

Next, FIG. 3D is a schematic cross-sectional side view of the multilevel wiring structure 300 at an intermediate stage of fabrication after performing a wafer thinning process to thin down the second substrate 320 to form a thinned substrate 320-1, and after patterning the thinned substrate 320-1 to form via and trench openings in the thinned substrate 320-1. The thinned substrate 320-1 serves as a low loss interlayer dielectric layer (with desired thickness T) of the multilevel wiring structure 100. As noted above, the wafer thinning process can be performed using known techniques including, but not limited to, backside wafer grinding, CMP, or a combination thereof, etc.

In addition, as schematically shown in FIG. 3D the thinned substrate 320-1 is patterned to form, e.g., a via opening 320a and a trench opening 320b. In an exemplary embodiment, the trench opening 320b defines an image of a metallization layer to be formed, in which the trench opening 320b is patterned to have a plurality of discontinuities 321a in which the substrate material is not removed within the footprint area of the trench opening 320b. In some embodiments, as noted above, the thinned substrate 320-1 is patterned using standard photolithography techniques for performing a dual damascene process in which the via opening 320a and the trench opening 320b are concurrently formed, followed by deposition of a superconducting metal to form a patterned metallization layer and interlayer via, such as shown in FIG. 3E.

In particular, FIG. 3E is a schematic cross-sectional side view of the multilevel wiring structure 300 at an intermediate stage of fabrication after filling the via and trench openings 320a and 320b of the thinned substrate 320-1 with a superconducting metal to form a metallization layer 321 and an interlayer via 322 which connects the metallization layer 321 to the underlying metallization layer 311 of the first substrate 310. The metallization layer 321 and the interlayer via 322 can be formed by depositing a superconducting metal (e.g., Al, Nb, Ta, Ti, W, Sn, Mo, or nitrides thereof, etc.) on the thinned substrate 320-1 to overfill the via and trench openings 320a and 320b with the superconducting metal, and then removing the excess (overburden) superconducting metal by performing, e.g., a CMP process to planarize down to the upper surface of the thinned substrate 320-1 to form the metallization layer 321 and the interlayer via 322.

In an exemplary embodiment, similar to the metallization layer 311 of the first substrate 310, the resulting metallization layer 321 is formed to have a plurality of discontinuities 321a which expose portions of the surface of the thinned substrate 320-1 to facilitate substrate-to-substrate bonding. Indeed, the formation of the discontinuities 321a in the metallization layer 321 allows sufficient substrate area to be exposed within the footprint area of the metallization layer 321 to ensure a good substrate-to-substrate bond in instances where the metallization layer 321 has a relatively large area, e.g., where the metallization layer 321 comprises a large-area ground plane in the given metallization level.

Next, FIG. 3F is a schematic cross-sectional side view of the multilevel wiring structure 300 at an intermediate stage of fabrication after bonding a third substrate 330 to the thinned substrate 320-1. In some embodiments, the third substrate 330 is formed of the same or similar low-loss (high resistivity) dielectric material as the first and second substrates 310 and 320. The third substrate 330 is bonded to the thinned substrate 320-1 using a substrate-to-substrate direct bonding process in which the surface of the third substrate 330 is bonded to exposed surfaces of the thinned substrate 320-1. The substrate-to-substrate bonding process is performed using any state-of-the-art direct bonding or fusion bonding process which is suitable to bond the material of the third substrate 330 with the material of the thinned substrate 320-1, the details of which are known to those of ordinary skill in the art.

Next, FIG. 3G is a schematic cross-sectional side view of the multilevel wiring structure 300 at an intermediate stage of fabrication after performing a wafer thinning process to thin down the third substrate 330 to form a thinned substrate 330-1 (which serves as in interlayer dielectric layer), and after forming another metallization layer 331 and an interlayer via 332 which connects the metallization layer 331 to the underlying metallization layer 321 of the thinned substrate 320-1. The wafer thinning process and metallization formation process are performed using the same or similar techniques as discussed above. The same process steps (e.g., FIGS. 3C, 3D, and 3E and/or FIGS. 3F and 3G) can be repeated one or more times to create additional wiring levels as needed.

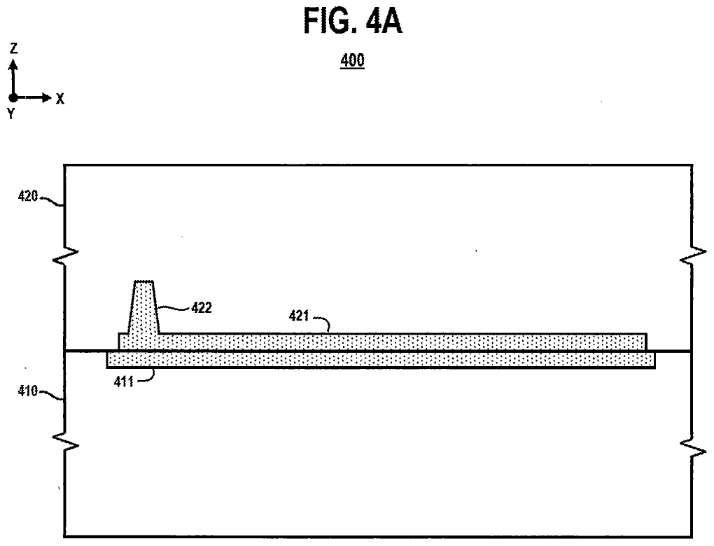

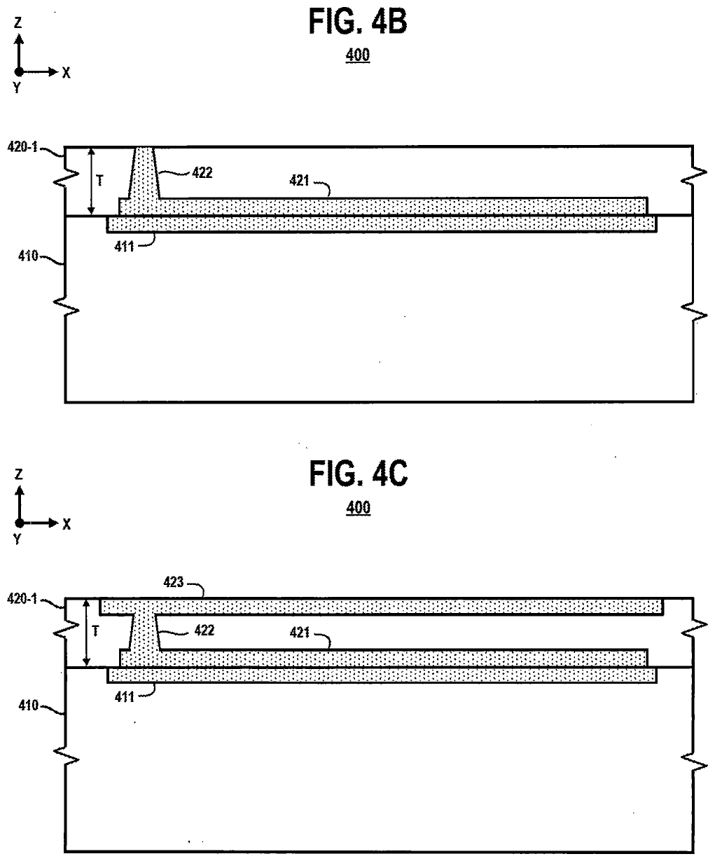

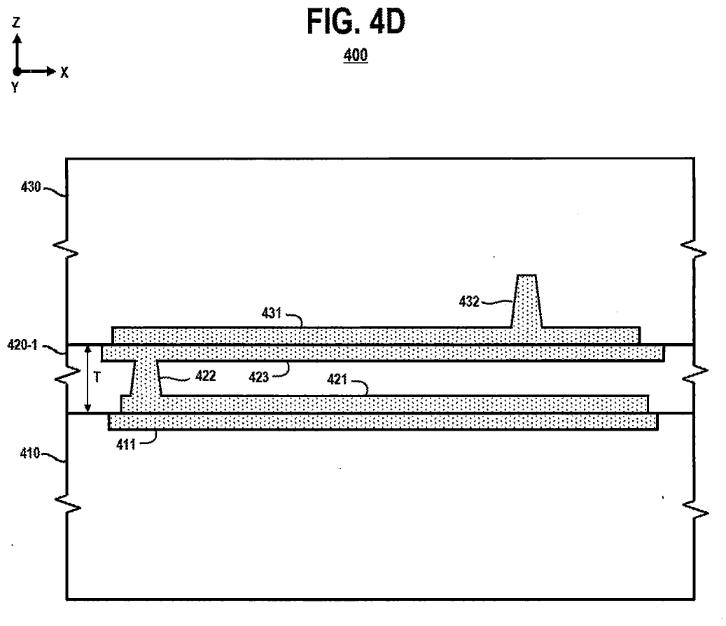

FIGS. 4A through 4D schematically illustrate a method for fabricating a multilevel wiring structure for a superconducting quantum device, according to another exemplary embodiment of the disclosure. In particular, FIGS. 4A through 4D schematically illustrate a method for fabricating a multilevel wiring structure which comprises (i) utilizing metal-to-metal bonding techniques to bond substrates that are formed of a low-loss (e.g., high resistivity) dielectric material (e.g., monocrystalline silicon), and (ii) utilizing substrate thinning techniques and backside via reveal methods to thin down the low-loss substrates to desired thicknesses. To begin, FIG. 4A is a schematic cross-sectional side view of a multilevel wiring structure 400 at an intermediate stage of fabrication after bonding a first substrate 410 (or support substrate 410) to a second substrate 420 by metal-to-metal bonding of metallization layers of the first and second substrates 410 and 420.

More specifically, as schematically illustrated in FIG. 4A, the first substrate 410 comprises a metallization layer 411 that is formed in a frontside surface of the first substrate 410, and the second substrate 420 comprises metallization layer 421 and interlayer via 422 formed in a surface of the second substrate 420. The first and second substrates 410 and 420 are formed of suitable low-loss substrate materials (e.g., monocrystalline silicon) as described above, and the metallization layers 411 and 421 and interlayer via 422 can be formed of any suitable superconducting metal as described above. The metallization layer 411 can be fabricated in the surface of the first substrate 410 using a single damascene process, and the metallization layer 421 and the interlayer via 422 can be concurrently fabricated in the surface of the second substrate 420 using a dual damascene process, as discussed above. The first and second substrates 410 and 420 are bonded together by metal-to-metal bonding of the metallization layers 411 and 421, using techniques such as described herein (e.g., a low-temperature UHV eutectic bonding process).

Next, FIG. 4B is a schematic cross-sectional side view of the multilevel wiring structure 400 at an intermediate stage of fabrication after performing a wafer thinning process to thin down the second substrate 420 and form a thinned substrate 420-1 which serves as an interlayer dielectric layer of the multilevel wiring structure 400. In particular, as schematically shown in FIG. 4B, a portion of the backside of the second substrate 420 is etched down to a level which reveals the embedded end of the interlayer via 422. It is to be noted that the backside etching of the second substrate 420 can be performed using any suitable via-reveal process which includes any combination of sequential etch steps including, e.g., wafer griding, dry etch, and/or wet etch steps, or a single etch step. In this instance, the “via reveal” process implements the embedded vias as an etch termination point to achieve target thickness T of the thinned substrate 420-1.

Next, FIG. 4C is a schematic cross-sectional side view of the multilevel wiring structure 400 at an intermediate stage of fabrication after forming a metallization layer 423 in the surface of the thinned substrate 420-1 in contact with the exposed end of the interlayer via 422. The metallization layer 423 can be formed using a single damascene process which involves patterning a trench in the surface of the thinned substrate 420-1, and depositing a superconducting metal (e.g., Al, Nb, Ta, Ti, W, Sn, Mo, or nitrides thereof, etc.) on the thinned substrate 420-1 to overfill the trench opening with the superconducting metal, and then removing the excess (overburden) superconducting metal by performing, e.g., a CMP process to planarize down to the upper surface of the thinned substrate 420-1 to form the metallization layer 423, wherein the metallization layer 423 is electrically connected to the underlying metallization layers 421 and 411 by the interlayer via 422.

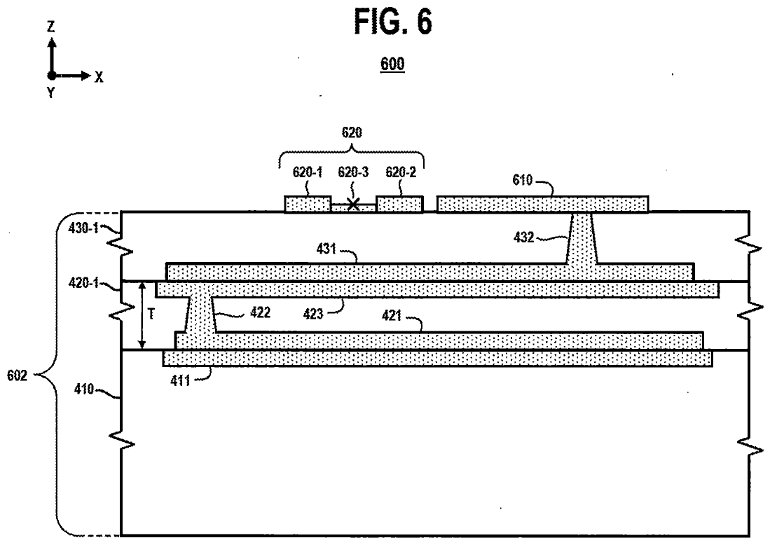

Next, FIG. 4D is a schematic cross-sectional side view of the multilevel wiring structure 400 at an intermediate stage of fabrication after bonding a third substrate 430 to the thinned substrate 420-1. The third substrate 430 comprises a metallization layer 431 and an interlayer via 432 formed in a surface of the third substrate 430. The third substrate 430 is formed of the same or similar low-loss substrate material (e.g., monocrystalline silicon) as the first and second substrates 410 and 420. The metallization layer 431 and the interlayer via 432 comprise the same or similar superconducting metal as the metallization layer 423, and can be formed using a dual damascene process, as discussed herein. The third substrate 430 and the thinned substrate 420-1 are bonded together by metal-to-metal bonding of the metallization layers 423 and 431, using techniques such as described herein (e.g., a low-temperature UHV eutectic bonding process). Following the bonding process, the backside of the third substrate 430 is etched down using a suitable via-reveal process to expose the embedded end of the interlayer via 432 and thereby form a thinned substrate which serves as another interlayer dielectric layer of the multilevel wiring structure 400 (an exemplary embodiment of which is shown in FIG. 6). Thereafter, the same process steps (e.g., FIGS. 4C and 4D) can be repeated one or more times to create additional wiring levels as needed. It is to be noted that while the exemplary fabrication process of FIGS. 4A through 4D is discussed in the context of utilizing metal-to-metal wafer bonding, the process flow is compatible with a hybrid bonding process which includes both metal-to-metal bonding and substrate-to-substrate bonding to bond wafers together.

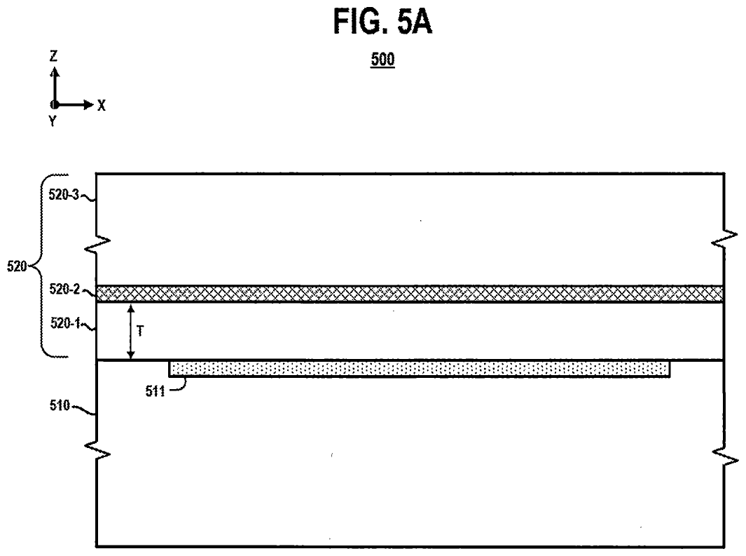

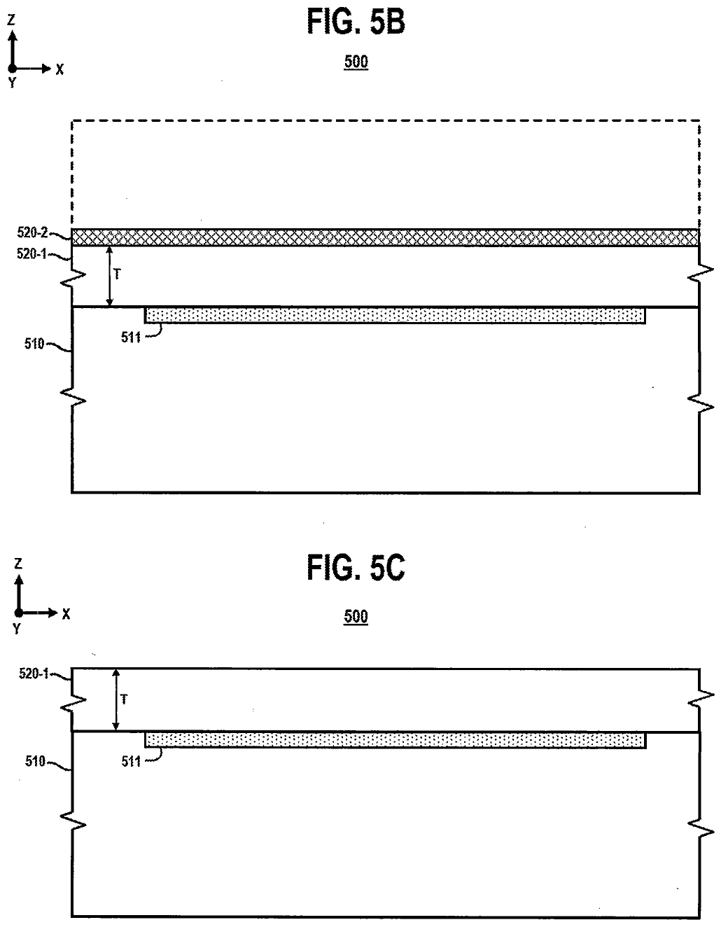

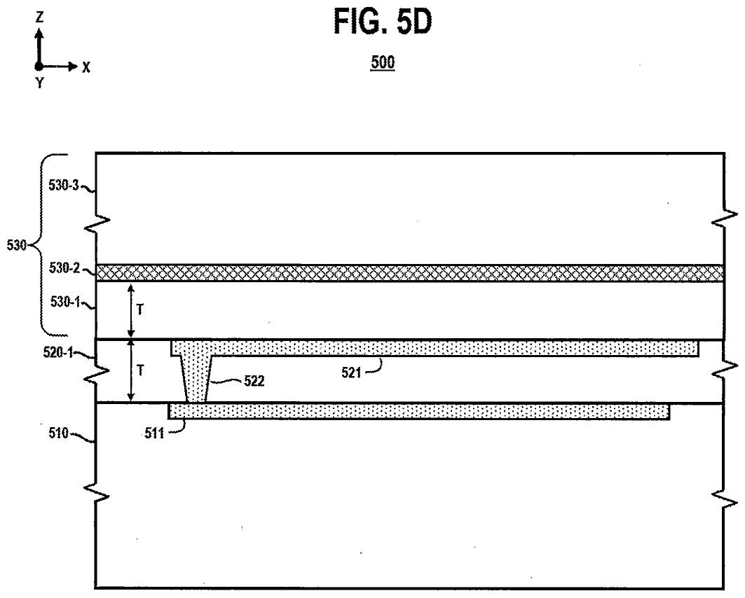

FIGS. 5A through 5D schematically illustrate a method for fabricating a multilevel wiring structure for a superconducting quantum device, according to another exemplary embodiment of the disclosure. In particular, FIGS. 5A through 5D schematically illustrate a method for fabricating a multilevel wiring structure which comprises (i) utilizing substrate-to-metal bonding techniques to bond substrates that are formed of low-loss substrate material (e.g., monocrystalline silicon) and which comprise etch stop layers, and (ii) utilizing substrate thinning techniques to thin down the low-loss substrates to form low-loss interlayer dielectric layers of the multilevel wiring structure having controlled thicknesses that are defined by the etch stop layers.

To begin, FIG. 5A is a schematic cross-sectional side view of a multilevel wiring structure 500 at an intermediate stage of fabrication after processing a first substrate 510 (or support substrate 510) to form a patterned layer of superconducting metal 511 (or metallization layer 511) in a surface of the first substrate 510, and after bonding a second substrate 520, which has an etch stop layer, to the first substrate 510 using a substrate-to-metal bonding process. The first substrate 510 is formed of a suitable low-loss (e.g., high resistivity) dielectric material (e.g., monocrystalline silicon) as described above, and the metallization layer 511 can be formed of a suitable superconducting metal as described above.

The second substrate 520 comprises a first substrate layer 520-1, an etch stop layer 520-2, and a second substrate layer 520-3. In general, the etch stop layer 520-2 comprises material that can be etched selective to the first substrate layer 520-1 and the second substrate layer 520-3. For example, in some embodiments, the second substrate 520 comprises a silicon on insulator (SOI) wafer, wherein the first substrate layer 520-1 comprises a thin layer of monocrystalline silicon (with thickness T), the etch stop layer 520-2 comprises a thin oxide layer (referred to as buried oxide layer), and the second substrate layer 520-3 comprises a thick bulk layer of monocrystalline silicon. In other embodiments, the etch stop layer 520-2 can be an epitaxial semiconductor layer which has etch selectivity to the semiconductor material of the first substrate layer 520-1. For example, in some embodiments, the first substrate layer 520-1 comprises monocrystalline silicon, and the etch stop layer 520-2 comprises a layer of epitaxial (crystalline) silicon germanium (SiGe), which can be etched selective to the crystalline silicon material of the first substrate layer 520-1.

Next, FIGS. 5B and 5C schematically illustrate a process for performing a controlled wafer thinning process on the second substrate 520 using the etch stop layer 520-2 of the second substrate 520. For example, FIG. 5B is a schematic cross-sectional side view of the multilevel wiring structure 500 at an intermediate stage of fabrication after removing the second (bulk) substrate layer 520-3 of the second substrate 520 down to the etch stop layer 520-2. In some embodiments, a wafer grinding process and/or CMP process is performed to remove the second (bulk) substrate layer 520-3 and expose the etch stop layer 520-2. For example, in some embodiments, a CMP process is performed to polish away the second (bulk) substrate layer 520-3 down to the etch sop layer 520-2, wherein the etch stop layer 520-2 essentially serves as a polish stop layer to terminate the CMP process. In another exemplary embodiment, the wafer thinning process comprises (i) performing an initial wafer grinding process to grind away most of the second (bulk) substrate layer 520-3, and (ii) performing an etch process (e.g., dry etch or wet etch process) to etch a remaining portion of the second (bulk) substrate layer 520-3, selective to the material of the etch stop layer 520-2, to complete the removal of the second (bulk) substrate layer 520-3 and expose the etch stop layer 520-3. The exposed etch stop layer 520-2 is then selectively etched using another etch process.

For example, FIG. 5C is a schematic cross-sectional side view of the multilevel wiring structure 500 at an intermediate stage of fabrication after removing the etch stop layer 520-2 down to the first substrate layer 520-1. In some embodiments, the etch stop layer 520-2 (e.g., oxide layer, epitaxial semiconductor layer, etc.) is removed using a dry etch process or wet etch process with an etch chemistry that is configured to etch the material of the etch stop layer 520-2 selective to the material of the first substrate layer 520-1. As a result of the controlled wafer thinning process, the first substrate layer 520-1 with the defined thickness T remains to serve as an interlayer dielectric layer in the multilevel wiring structure 500.

Following the controlled wafer thinning process, the first substrate layer 520-1 is processed to form interlayer vias and a metallization pattern using, e.g., single damascene or dual damascene processes such as described above, and another substrate (e.g., SOI wafer) is bonded to the first substrate layer 520-1 and thinned to form another interlayer dielectric layer of the multilevel wiring structure 500. For example, FIG. 5D is a schematic cross-sectional side view of the multilevel wiring structure 500 at an intermediate stage of fabrication after forming a metallization layer 521 and interlayer via 522 in the first substrate layer 520-1, and after bonding a third substrate 530 to the first substrate layer 520-1. Similar to the second substrate 520, the third substrate 530 comprises a first substrate layer 530-1, an etch stop layer 530-2, and a second (bulk) substrate layer 530-3. The third substrate 530 can be, e.g., an SOI wafer, or any other type of substrate in which the etch stop layer 530-2 is formed of a material that can be etched selective to the material of the first substrate layer 530-1. The same process steps of, e.g., FIGS. 5B and 5C can be performed to sequentially remove the second (bulk) substrate layer 530-3 and the etch stop layer 530-2, with the first substrate layer 530-1 (with thickness T) remaining to serve as a next interlayer dielectric layer of the multilevel wiring structure 500. In addition, the process flow shown in FIGS. 5B-5D can be repeated one or more times to create additional wiring levels as needed.

It is to be noted that while the exemplary fabrication process of FIGS. 5A through 5D is discussed in the context of utilizing substrate-to-metal wafer bonding, the process flow is compatible with a hybrid bonding process which includes both substrate-to-metal bonding and metal-to-metal bonding to bond wafers together. For example, in some embodiments, the second and third substrates 520 and 530 can be processed prior to bonding to form metallization layers (and possible interlayer vias) in the first substrate layers 520-1 and 530-1 thereof before bonding the second substrate 520 to the first substrate 510 (in FIG. 5A) and before bonding the second substrate 520 to the first substrate layer 520-1 (in FIG. 5D).

Moreover, it is to be noted that the schematic illustrations of the multilevel wiring structures 100, 200, 300, 400, and 500 are meant to show general architectures of multilevel wiring structures having metallization layers and interlayer vias, for the purpose of describing the various types of wafer bonding processes, e.g., metal-to-metal, substrate-to-metal, substrate-to-substrates, and hybrids thereof, which can be used to form multilevel wiring structures with low loss interlayer dielectric layers that are formed by thinning low loss substates (e.g., low loss crystalline semiconductor wafers). The fabrication methods as discussed herein could be utilized to fabricate multilevel wiring structures that are designed to have specific patterned metallization layers and arrangement of interlayer via connections, as needed, to provide a desired network of wiring and interlevel via connections for a given application.

For example, in some embodiments, the different metallization layers (or metallization levels) would include respective ground planes, where all the ground planes of the different metallization levels would be commonly coupled using interlayer ground vias formed in the interlayer dielectric layers. In addition, some or all of the metallization layers would have planar signal transmission lines, resonators, qubit control lines, etc., which are formed as, e.g., coplanar waveguides (CPWs), and interlayer vias to connect planar signals lines on different metallization levels. In some embodiments, a given metallization layer comprising CPW transmission lines would be disposed between upper and/or lower metallization layers comprising large ground planes to provide grounded CPW architectures.

In other embodiments, wafer-bonded multilevel wiring structures are integrated or otherwise combined with superconducting qubits or qubit chips or other superconducting quantum circuit components using various methods, exemplary embodiments of which are schematically illustrated in FIGS. 6, 7, and 8. For example, FIGS. 6, 7, and 8 schematically illustrate quantum chips having integrated low-loss multilevel wiring structures, according to exemplary embodiments of the disclosure. In particular, FIG. 6 is a schematic cross-sectional side view of a quantum device 600 (or quantum chip) which comprises a multilevel wiring structure 602 having a final metallization level which comprises a patterned metallization layer 610 and at least one superconducting qubit 620.

In the exemplary embodiment shown in FIG. 6, the multilevel wiring structure 602 is shown to be the exemplary multilevel wiring structure 400 shown in FIG. 4D after etching down the backside of the third substrate 430 using a via-reveal process to expose the embedded end of the interlayer via 432 and thereby form a thinned substrate 430-1 which serves as a final interlayer dielectric layer of the multilevel wiring structure 602. The metallization layer 610 and the superconducting qubit 620 are formed on the surface of the thinned substrate 430-1 using known techniques. In this exemplary architecture, the superconducting qubit 620 and other superconducting qubits, readout resonators, and couplers, etc., can be integrally formed as part of the final metallization layer of the multilevel wiring structure 602.

In an exemplary embodiment, the superconducting qubit 620 comprises a superconducting transmon qubit which comprises a first superconducting capacitor pad 620-1, a second superconducting capacitor pad 620-2, and a Josephson junction 620-3 connected to and between the first and second superconducting capacitor pads 620-1 and 620-2. As is known in the art, a superconducting transmon qubit is a qubit which comprises a superconducting capacitor coupled in parallel with a Josephson junction. In FIG. 6, the first and second superconducting capacitor pads 620-1 and 620-2 comprise first and second capacitor electrodes of a coplanar parallel plate capacitor, which is connected in parallel with the Josephson junction 620-3.

While FIG. 6 illustrates only one superconducting qubit 620 for ease of illustration and explanation, it is to be understood that multiple superconducting qubits can be formed on the upper surface of the thinned substrate 430-1, as well as other superconducting quantum circuit component such as qubit couplers, readout resonators, etc. In addition, the superconducting qubits that are formed on the upper surface of the thinned substrate 430-1 can be electrically coupled via resonators and other interconnects that are formed in one or more metallization levels of the multilevel wiring structure 602, as is understood by those of ordinary skill in the art.

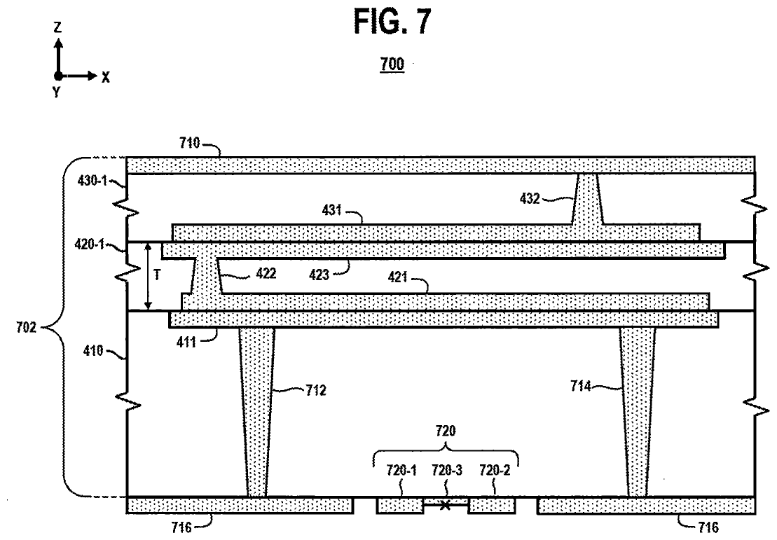

Next, FIG. 7 schematically illustrates a quantum device which comprises a multilevel wiring structure having integrated superconducting qubits, according to another exemplary embodiment of the disclosure. In particular, FIG. 7 is a schematic cross-sectional side view of a quantum device 700 (or quantum chip) which comprises a low-loss multilevel wiring structure 702 having metallization and interlayer dielectric layers formed on a first side (e.g., top side) of the support (handle) substrate, and superconducting qubits and other superconducting quantum circuit components formed on a second side (e.g., bottom side) of the support (handle) substrate. For illustrative purposes, the multilevel wiring structure 702 in FIG. 7 has an architecture which is similar to the exemplary multilevel wiring structure 400 shown in FIG. 4D, but wherein the third substrate 430 it thinned down as part of a via-reveal process to expose the embedded end of the interlayer via 432 and thereby form a thinned substrate 430-1, and wherein a metallization layer 710 is formed on an upper surface of the thinned substrate 430-1.

Moreover, FIG. 7 illustrates an exemplary embodiment in which the support (handle) substrate 410 comprises through-substrate vias (TSVs) 712 and 714 which are formed in the support substrate 410, and a patterned metallization layer 716 and at least one superconducting qubit 720, which are formed on the backside surface of the support substrate 410. In an exemplary embodiment, the superconducting qubit 720 comprises a superconducting transmon qubit which comprises a first superconducting capacitor pad 720-1, a second superconducting capacitor pad 720-2, and a Josephson junction 720-3 connected to and between the first and second superconducting capacitor pads 720-1 and 720-2. The first and second superconducting capacitor pads 720-1 and 720-2 comprise first and second capacitor electrodes of a coplanar parallel plate capacitor, which is connected in parallel with the Josephson junction 720-3.

As schematically illustrated in FIG. 7, the TSVs 712 and 714 are configured to connect the metallization layer 411 on the frontside of the support substrate 410 with the patterned metallization layer 716 on the backside of the support substrate 410. The multilevel wiring structure 702 can be fabricated using any suitable process such as shown in FIGS. 4A through 4D. However, in some embodiments, for the initial stage of the fabrication process, the support substrate 410 can be initially formed with the metallization layer 411 as well as the TSVs 712 and 714 embedded in the support substrate 410. After forming the final interlayer dielectric layer and metallization layer on the frontside of the support substrate 410, a via reveal process can be performed to etch the backside of the support substrate 410 to reveal the embedded ends of the TSVs 712 and 714. Thereafter, the patterned metallization layer 716 and superconducting qubit 720 can be fabricated using known methods on the backside surface of the support substrate 410 such that the patterned metallization layer 716 is formed in electrical contact with the exposed ends of the TSVs 712 and 714.

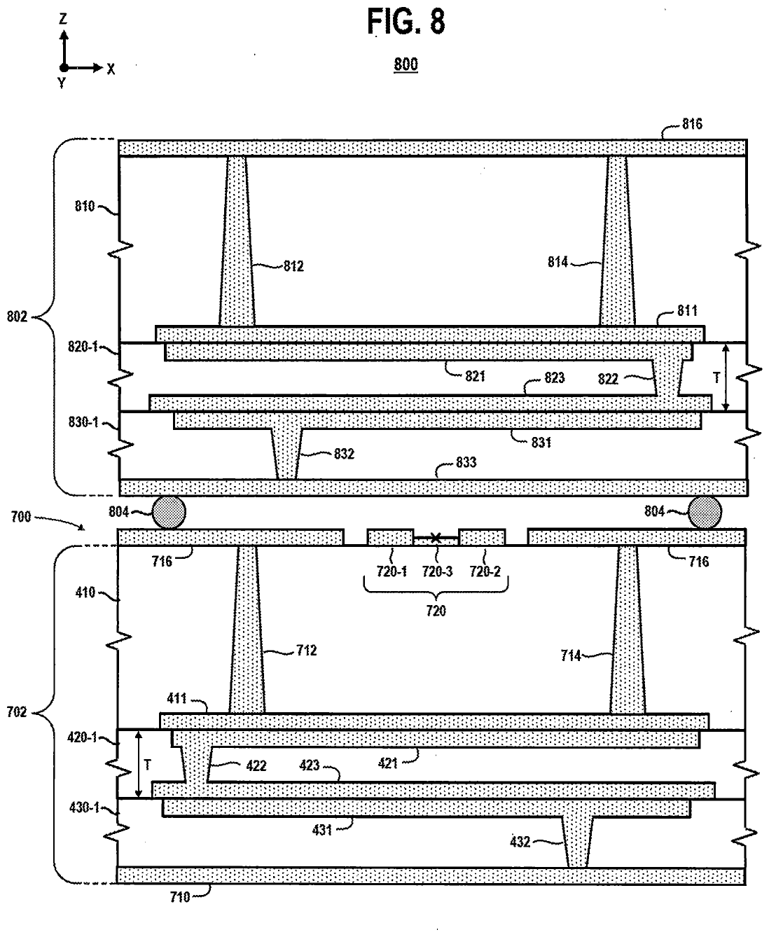

Next, FIG. 8 schematically illustrates a quantum device which comprises a multilevel wiring structure having integrated superconducting qubits, according to another exemplary embodiment of the disclosure. In particular, FIG. 8 is a schematic cross-sectional side view of a quantum device 800 (or quantum chip package structure) which comprises the exemplary quantum device 700 of FIG. 7 (having the multilevel wiring structure 702), and a second multilevel wiring structure 802 which is connected to the patterned metallization layer 716 of the quantum device 700 using bump connections 804. With this exemplary architecture, the superconducting quantum circuit components (e.g., superconducting qubit 720) can be connected, and control lines can be routed to the quantum circuit components, using two multilevel wiring structures 702 and 802.

As schematically illustrated in FIG. 8, the second multilevel wiring structure 802 comprises a first substrate 810 (or support substrate 810) and multiple interlayer dielectric layers which comprise thinned substrates 820-1 and 830-1 having a low-loss material (e.g., monocrystalline silicon). The support substrate 810 comprises a first patterned metallization layer 811 formed on a frontside thereof, a plurality of TSVs 812 and 814 formed in the support substrate 810, and a second metallization layer 816 (e.g., ground plane) formed on a backside of the support substrate 810. The thinned substrate 820-1 comprises a first patterned metallization layer 821, an interlayer via 822, and a second patterned metallization layer 823. The thinned substrate 830-1 comprises a first metallization layer 831, an interlayer via 832, and a second patterned metallization layer 833 (e.g., ground plane).

The first substrate 810 and the thinned substrate 820-1 are bonded via a metal-to-metal bonding of the patterned metallization layers 811 and 821. The thinned substrates 820-1 and 830-1 are bonded via a metal-to-metal bonding of the metallization layers 823 and 831. The second multilevel wiring structure 802 is formed using exemplary fabrication methods as discussed above, the details of which need not be repeated. In an exemplary embodiment, the quantum device 700 with the multilevel wiring structure 702 and superconducting qubits and associated circuitry is fabricated separately from the second multilevel wiring structure 802, and then second multilevel wiring structure 802 is connected to the quantum device 700 by the bump connections 804, using suitable solder bump formation and bonding techniques. In another exemplary embodiment, a quantum chip package structure can be implemented which is similar to the quantum device 800 of FIG. 8, but where the second multilevel wiring structure 802 is flipped such that the second metallization layer 816 is connected to the multilevel wiring structure 702 via the bump connections 804.

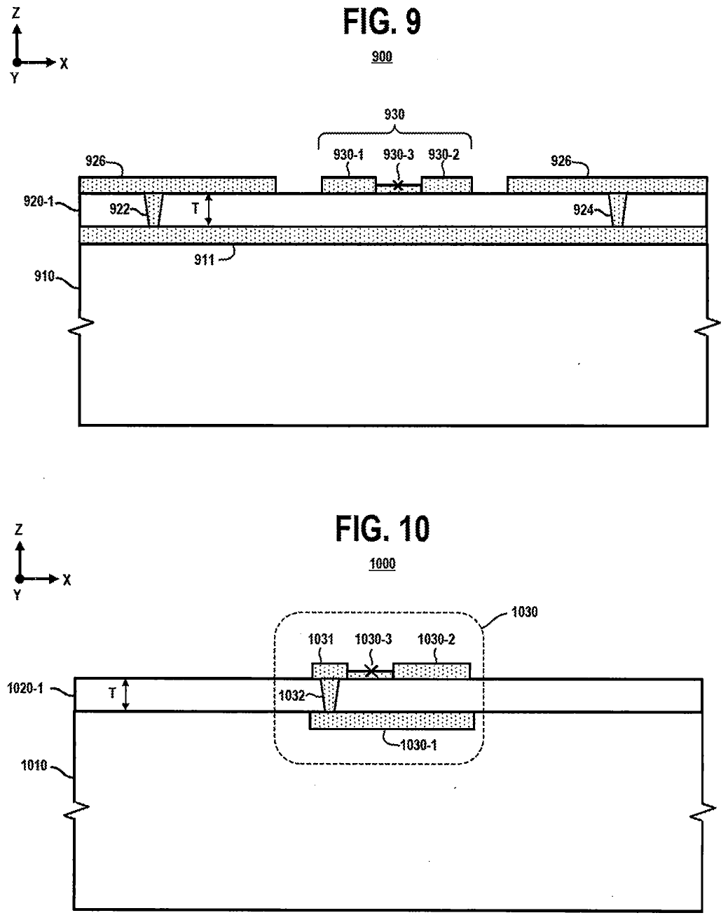

In other embodiments, the exemplary wafer bonding and thinning techniques discussed herein can be utilized to build various types of multilevel superconducting qubit structures having contact pads and/or capacitor structures that are formed on multiple metallization levels, exemplary embodiments of which are schematically illustrated in FIGS. 9, 10, and 11. For example, FIG. 9 is a schematic cross-sectional side view of a quantum device 900 which comprises a multilevel superconducting qubit structure, according to an exemplary embodiment of the disclosure. The quantum device 900 comprises a first substrate 910 (or support substrate 910) with a metallization layer 911 formed on a frontside of the support substrate 910, and a thinned substrate 920-1 which is bonded to the support substrate 910 by, e.g., substrate-to-metal bonding of the thinned substrate 920-1 and the metallization layer 911. The thinned substrate 920-1 comprises vias 922 and 924 formed in the thinned substrate 920-1, and a patterned metallization layer 926 and superconducting qubit 930 formed on a surface of the thinned substrate 920-1.

The thinned substrate 920-1 comprises a layer of low-loss dielectric material with a thickness T. The thinned substrate 920-1 is formed by, e.g., bonding a second substrate (e.g., a monocrystalline silicon substrate) to the support substrate 910 by substrate-to-metal bonding, and performing a backside thinning process to thin down the second substrate to a target thickness and thereby form the thinned substrate 920-1. In some embodiments, the vias 922 and 924 are formed by etching via openings in the thinned substrate 920-1 down to the metallization layer 911, depositing a superconducting metal to overfill the via openings with the superconducting metal, followed by a CMP process to remove the overburden superconducting metal down to the surface of the thinned substrate 920-1. The patterned metallization layer 926 and superconducting qubit 930 are then formed using known materials and methods.

The superconducting qubit 920 comprises a superconducting transmon qubit which comprises a first superconducting capacitor pad 930-1, a second superconducting capacitor pad 930-2, and a Josephson junction 930-3 connected to and between the first and second superconducting capacitor pads 930-1 and 930-2. In addition, in an exemplary embodiment, the metallization layer 911 on the support substrate 910 serves as a ground plane (e.g., actual or virtual ground) which is disposed from the first and second superconducting capacitor pads 930-1 and 930-2 at a well defied distance (defined by the thickness T of the thinned substrate 920-1), which enhances the capacitive coupling between the first and second superconducting capacitor pads 930-1 and 930-2 of the superconducting qubit 930.

Next, FIG. 10 is a schematic cross-sectional side view of a quantum device 1000 which comprises a multilevel superconducting qubit structure, according to another exemplary embodiment of the disclosure. The quantum device 1000 comprises a first substrate 1010 (or support substrate 1010), a thinned substrate 1020-1 (with thickness T) bonded to the support substrate 1010, and a superconducting qubit 1030 that is formed using two metallization levels. In particular, the superconducting qubit 1030 comprises a first superconducting capacitor pad 1030-1, a second superconducting capacitor pad 1030-2, and a Josephson junction 1030-3. The first and second superconducting capacitor pads 1030-1 and 1030-2 form a superconducting capacitor of the superconducting qubit 1030, wherein the superconducting capacitor is connected in parallel with the Josephson junction 1030-3.

In the exemplary embodiment shown in FIG. 10, the first superconducting capacitor pad 1030-1 of the superconducting qubit 1030 comprises a patterned metallization layer that is formed in the frontside surface of the first (support) substrate 1010 by, e.g., a damascene process. The second superconducting capacitor pad 1030-2 of the superconducting qubit 1030 comprises a patterned metallization layer that is formed on the surface of the thinned substrate 1020-1 in alignment with the first superconducting capacitor pad 1030-1 of the superconducting qubit 1030. The Josephson junction 1030-3 is formed on the surface of the thinned substrate 1020-1, and has one terminal which is connected to the second superconducting capacitor pad 1030-2, and another terminal which is connected to a contact pad 1031 that is formed as part of the patterned metallization layer on the surface of the thinned substrate 1020-1. An interlayer via 1032 formed in the thinned substrate 1020-1 provides a connection between the contact pad 1031 and the first superconducting capacitor pad 1030-1, thereby providing a direct connection of the Josephson junction 1030-2 to the first superconducting capacitor pad 1030-1. It is to be noted that the exemplary quantum device 1000 of FIG. 10 can be fabricated using any of the exemplary wafer bonding, wafer thinning, and metallization methods as described herein, the details of which will not be repeated.

The exemplary qubit architecture shown in FIG. 10 provides a smaller footprint area for a superconducting qubit by having the capacitor electrodes disposed in alignment with each other on separate metallization levels to provide a parallel plate capacitor, as opposed to a coplanar capacitor configuration formed on a single metallization level. In addition, the exemplary qubit architecture provides a well-controlled capacitance that can be achieved based on, e.g., the overlap area of the first and second superconducting capacitor pads 1030-1 and 1030-2 on the different metallization layers, and the distance between the first and second superconducting capacitor pads 1030-1 and 1030-2 as defined by the thickness T of the thinned substrate 1020-1.

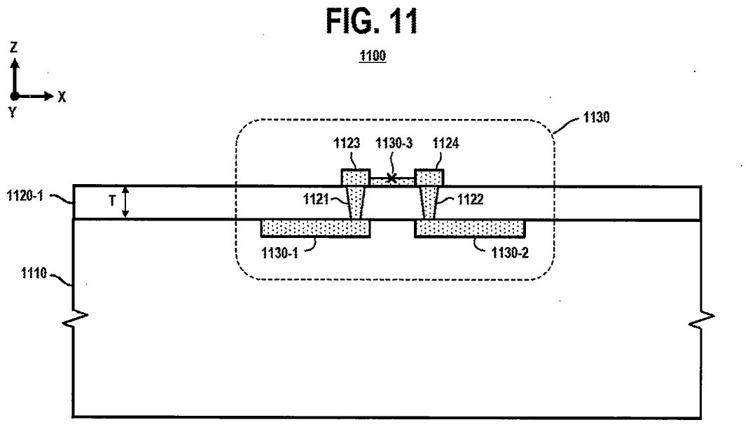

Next, FIG. 11 is a schematic cross-sectional side view of a quantum device 1100 which comprises a multilevel superconducting qubit structure, according to another exemplary embodiment of the disclosure. The quantum device 1100 comprises a first substrate 1110 (or support substrate 1110), a thinned substrate 1120-1 (with thickness T) bonded to the support substrate 1110, and a superconducting qubit 1130 that is formed using two metallization levels. In particular, the superconducting qubit 1130 comprises a first superconducting capacitor pad 1130-1, a second superconducting capacitor pad 1130-2, and a Josephson junction 1130-3. The first and second superconducting capacitor pads 1130-1 and 1130-2 form a coplanar superconducting capacitor of the superconducting qubit 1130, wherein the coplanar superconducting capacitor is connected in parallel with the Josephson junction 1130-3.

In the exemplary embodiment shown in FIG. 11, the first and second superconducting capacitor pads 1130-1 and 1130-2 of the superconducting qubit 1130 are formed as part of a patterned metallization layer that is formed in the frontside surface of the first (support) substrate 1110 by, e.g., a damascene process. The thinned substrate 1120-1 comprises interlayer vias 1121 and 1122 formed therein, and a patterned metallization layer which comprises contact pads 1123 and 1124 formed on a surface of the thinned substrate 1120-1. The Josephson junction 1130-3 is formed on the surface of the thinned substrate 1120-1. The Josephson junction 1130-3 has a first terminal which is connected to the first superconducting capacitor pad 1130-1 through the contact pad 1123 and the interlayer via 1121, and a second terminal which is connected to the second superconducting capacitor pad 1130-2 through the contact pad 1124 and the interlayer via 1122. It is to be noted that the exemplary quantum device 1100 of FIG. 11 can be fabricated using any of the exemplary wafer bonding, wafer thinning, and metallization methods as described herein, the details of which will not be repeated.

It is to be understood that while FIGS. 10, 11, and 12 schematically illustrate different multilevel superconducting qubit structures that are formed on a support substrate, the same techniques for constructing such multilevel superconducting qubit structures on support substrates can be utilized to form such multilevel superconducting qubit structures in upper metallization layers of a low-loss multilevel wiring structure. For example, in the exemplary embodiments of FIGS. 6, 7 and 8, the superconducting qubits 620 and 720 can be fabricated as multilevel superconducting qubit structures as shown in FIGS. 10, 11, and 12.

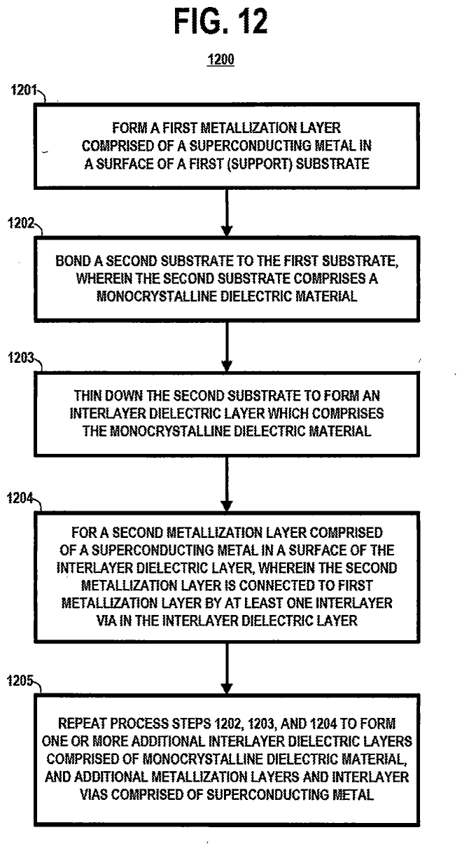

FIG. 12 illustrates a flow diagram of a process for fabricating a multilevel wiring structure of a superconducting quantum device, according to an exemplary embodiment of the disclosure. In particular, the flow diagram of FIG. 12 depicts a high-level fabrication process 1200 for constructing a multilevel wiring structure, which is based on the exemplary fabrication processes discussed above in conjunction with, e.g., FIGS. 1A-1K, FIGS. 2A-2F, 3A-3G, 4A-D, and 5A-5D. An initial stage of the fabrication process 1200 for constructing a multilevel wiring structure comprises forming a first metallization layer, which is comprised of a superconducting metal, in a surface of a first (support) substrate (block 1201). Next, a second substrate is bonded to the first substrate, wherein the second substrate comprises a monocrystalline dielectric material (block 1202). A wafer thinning process is performed to thin the second substrate to form an interlayer dielectric layer which comprises the monocrystalline dielectric material (block 1203). Next, a second metallization layer comprising a superconducting metal is formed in a surface of the interlayer dielectric layer, wherein the second metallization layer is connected to the first metallization layer by at least one interlayer via in the interlayer dielectric layer (block 1204). The process steps of blocks 1202, 1204, and 1204 are repeated one or more times to form one or more additional interlayer dielectric layers comprised of monocrystalline dielectric material, and additional metallization layers and interlayer vias comprised of superconducting metal (block 1205).

As noted above, in some embodiments, the first substrate and the second substrate are formed of a monocrystalline semiconductor material such as monocrystalline silicon. Moreover, in some embodiments, the bonding process (block 1202) can be performed using one or more of a substrate-to-metal bonding process, a substrate-to-substrate bonding process, and metal-to-metal bonding process. While the exemplary substrate bonding techniques are described herein in the contest of wafer bonding, it is to be understood that chip-to-chip and/or chip-to-wafer bonding techniques can be utilized to fabricate quantum chip package structures and quantum devices having low-loss multilevel wiring structures.

While exemplary embodiments have been discussed in the context of utilizing damascene techniques (e.g., single or dual damascene) to form patterned metallization layers, it is to be understood that other suitable techniques can be utilized to form patterned metallization layers of multilevel wiring structure. For example, other patterning methods to define metallization layers include, but are not limited to, subtractive etch methods, sidewall image transfer methods (e.g., spacer formation), etc. The exemplary structures in the drawings are schematically illustrated as having planar surfaces corresponding to bonding surfaces, since the regions that form the bonds are ideally flat to form good bonds. However, in some embodiments, patterned regions that are not used for bonding, in cases where they exist, may be recessed relative to the surface regions that are involved in the bonding of the substrates.

Further, as noted above, the substrate thinning process (block 1203) can be performed using mechanical etching techniques (e.g., wafer grinding, CMP, etc.). In some embodiments, where the substrate comprises an embedded etch stop layer, the substrate thinning process is performed by etching the backside of the substrate down to the etch stop layer, and removing the etch stop layer using an etch process (dry etch process, wet etch process) which is selective to the monocrystalline dielectric material of the substrate to form the interlayer dielectric layer which comprises a remaining portion of the substrate after removing etch stop layer. In other embodiments, where the substrate comprises an embedded via, the substrate thinning process is performed by performing a via reveal etch process to etch the substrate down to a level which reveals an end portion of the embedded via.

Advantageously, wafer bonding and wafer thinning techniques are implemented to form multilevel wiring structures having low-loss interlayer dielectric layers. For example, as noted above, the exemplary wafer bonding and wafer thinning techniques allow the formation of low microwave loss multilevel wiring structures having low-loss monocrystalline dielectric layers (e.g., monocrystalline silicon), which allows various types of superconducting quantum devices to be integrated within such low-loss multilevel wiring structures. This is in contrast to conventional methods for fabricating multilevel wiring structures in which interlayer dielectric layer having amorphous or polycrystalline dielectric material are formed using deposition techniques such as CVD or plasma-enhanced (PE) CVD techniques.

For example, as discussed above in conjunction with, e.g., FIGS. 6, 7, 8, 9, 10, and 11, in some embodiments, a plurality of superconducting qubits (e.g., qubit array) can be fabricated in a given metallization level (e.g., final metallization level) of a low-loss multilevel wiring structure. It is to be noted that while exemplary embodiment of the disclosure are discussed in the context of transmon qubits for illustrative purposes, such superconducting qubits can include other types of qubits which comprise, e.g., one or more Josephson junctions and superconducting capacitors, such as fluxonium qubits, multimode qubits (e.g., two-junction qubits, or tunable coupling qubits), and other suitable types of fixed-frequency qubits or tunable-frequency qubits. Moreover, tunable qubit couplers (e.g., frequency-tunable qubits) can be fabricated in a given metallization level of the low-loss multilevel wiring structure to control/mediate interactions (e.g., entanglement gate operations) between superconducting qubits. The implementation of low-loss interlayer dielectric layers in a multilevel wiring structure allows the integration of superconducting qubits within the multilevel wiring structure, while maintaining high coherence through the use of such low-loss interlayer dielectric layers.

Moreover, other types of superconducting quantum devices and circuitry which can be integrated within a low-loss multilevel wiring structure include, but are not limited to, high quality factor resonators (e.g., readout resonators), qubit coupling buses, coupler drive lines, qubit drive lines, and other signal I/O lines and control lines. Such superconducting devices and circuitry include features that are patterned on one or more metallization levels and connected by interlayer vias, which are all comprised of superconducting metal. In this regard, the integration of superconducting quantum devices and circuitry within a low-loss multilevel wiring structure enables higher connectivity routing and greater quantum circuit density, as well as enable a space saving structure that supports continued scaling.

Indeed, the integration of superconducting quantum devices and circuitry within a low-loss multilevel wiring structure allows for greater circuit density in terms of number of quantum devices per square area, which increases the plausible computational power of quantum processors. Indeed, a smaller horizontal footprint can be achieved by incorporating superconducting qubits on one metallization level, while incorporating the associated readout resonators of the superconducting qubits in other metallization levels. Moreover, long range on-chip couplers can be routed through a low-loss multilevel wiring structure, and possibly decrease the coupling distance by avoiding Manhattan style routing. By constructing a low-loss multilevel wiring structure having a sufficient number of layers, many quantum device and circuit components can be integrated within the low-loss multilevel wiring structure, thereby allowing further scaling by, e.g., increasing a number of qubit-to-qubit connections using low-loss connections that routed through the low-loss multilevel wiring structure.

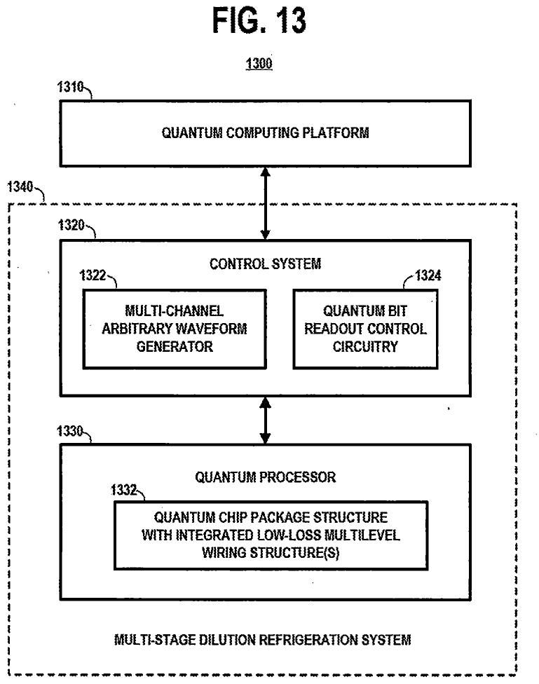

FIG. 13 schematically illustrates a quantum computing system which comprises a quantum processor which comprises a multilevel wiring structure having integrated superconducting qubits, according to an exemplary embodiment of the disclosure. In particular, FIG. 13 schematically illustrates a quantum computing system 1300 which comprises a quantum computing platform 1310, a control system 1320, and a quantum processor 1330. In some embodiments, the control system 1320 comprises a multi-channel arbitrary waveform generator 1322, and quantum bit readout control circuitry 1324. In an exemplary embodiment, the quantum processor 1330 comprises at least one quantum chip package structure 1332 with one or more integrated low-loss multilevel wiring structures. For example, the quantum chip package structure 1332 can be implemented using any one of the exemplary package structures shown in FIGS. 7, 8, 9, 10, and 11, as may be needed for a given application or quantum system configuration.

In some embodiments, the control system 1320 and the quantum processor 1330 are disposed in a dilution refrigeration system 1340 which can generate cryogenic temperatures that are sufficient to operate components of the control system 1320 for quantum computing applications. For example, the quantum processor 1330 may need to be cooled down to near-absolute zero, e.g., 6-15 millikelvin (mK), to allow the superconducting qubits to exhibit quantum behaviors. In some embodiments, the dilution refrigeration system 1340 comprises a multi-stage dilution refrigerator where the components of the control system 1320 can be maintained at different cryogenic temperatures, as needed. For example, while the quantum processor 1330 may need to be cooled down to, e.g., 10-15 mK, the circuit components of the control system 1320 may be operated at cryogenic temperatures greater than 10-15 mK, depending on the configuration of the quantum computing system. In other embodiments, some components of the control system 1320 may comprise electronic components that are disposed and operated in a room temperature environment.

In some embodiments, the multi-channel arbitrary waveform generator (AWG) 1322 and other suitable microwave pulse signal generators are configured to generate the microwave control pulses that are applied to the qubit drive lines, and the coupler drive lines to control the operation of the superconducting qubits and associated qubit coupler circuitry, when performing various gate operations to execute a given certain quantum information processing algorithm. In some embodiments, the multi-channel AWG 1322 comprises a plurality of AWG channels, which control respective superconducting qubits on qubit chips within the quantum chip package structure 1332 of the quantum processor 1330. In some embodiments, each AWG channel comprises a baseband signal generator, a digital-to-analog converter (DAC) stage, a filter stage, a modulation stage, and an impedance matching network, and a phase-locked loop system to generate local oscillator (LO) signals (e.g., quadrature LO signals LO_I and LO_Q) for the respective modulation stages of the respective AWG channels.

In some embodiments, the multi-channel AWG 1322 comprises a quadrature AWG system which is configured to process quadrature signals, wherein a quadrature signal comprises an in-phase (I) signal component, and a quadrature-phase (Q) signal component. In each AWG channel the baseband signal generator is configured to receive baseband data as input (e.g., from the quantum computing platform), and generate digital quadrature signals I and Q which represent the input baseband data. In this process, the baseband data that is input to the baseband signal generator for a given AWG channel is separated into two orthogonal digital components including an in-phase (I) baseband component and a quadrature-phase (Q) baseband component. The baseband signal generator for the given AWG channel will generate the requisite digital quadrature baseband IQ signals which are needed to generate an analog waveform (e.g., sinusoidal voltage waveform) with a target center frequency that is configured to operate or otherwise control a given quantum bit that is coupled to the output of the given AWG channel.

The DAC stage for the given AWG channel is configured to convert a digital baseband signal (e.g., a digital IQ signal output from the baseband signal generator) to an analog baseband signal (e.g., analog baseband signals I(t) and Q(t)) having a baseband frequency. The filter stage for the given AWG channel is configured to the filter the IQ analog signal components output from the DAC stage to thereby generate filtered analog IQ signals. The modulation stage for the given AWG channel is configured to perform analog IQ signal modulation (e.g., single-sideband (SSB) modulation) by mixing the filtered analog signals I(t) and Q(t), which are output from the filter stage, with quadrature LO signals (e.g., an in-phase LO signal (LO_I) and a quadrature-phase LO signal (LO_Q)) to generate and output an analog RF signal (e.g., a single-sideband modulated RF output signal).

In some embodiments, the quantum bit readout control circuitry 1324 comprises a microwave pulse signal generator that is configured to applying a microwave tone to a given readout resonator line of a given superconducting qubit to perform a readout operation to readout the state of the given superconducting qubit, as well as circuitry that is configured to process the readout signal generated by the readout resonator line to determine the state of the given superconducting qubit, using techniques known to those of ordinary skill in the art. For example, in some embodiments, a qubit readout line for a given qubit comprise a coplanar waveguide resonator that is configured to have a resonant frequency that is detuned from a transition frequency of the given qubit to enable a dispersive readout operation for reading the quantum state of a given qubit which is coupled to a given readout resonator. A dispersive readout operation involves applying an RF readout control signal (RF_RO) to the given readout resonator, and detecting/processing the readout signal that is reflected out from the given readout resonator. An RF readout control signal that is applied to the given readout resonator has a single frequency tone that is the same or similar to the resonant frequency of the readout resonator, a pulse envelope with a given pulse shape (e.g., gaussian pulse envelope), and given pulse duration. In the dispersive regime of qubit-resonator coupling, the RF readout control signal interacts with the given qubit/resonator system, and the resulting output readout signal which is reflected out from the given readout resonator comprises information (e.g., phase and/or amplitude) that is qubit-state dependent. The quantum bit readout control circuitry 1324 can include various components in qubit readout signal chains including, e.g., microwave isolators, quantum-limited amplifiers (e.g., Josephson junction traveling wave parametric amplifiers), filters, other amplifiers such as high-electron-mobility-transistor (HEMT) amplifiers, etc., which are disposed in stages of the dilution refrigeration system, as well as IQ mixers, and analog-to-digital converter (ADC) circuitry, which outputs digital readout signals to a hardware or software based discriminators to determine the readout quantum state of superconducting qubits.

The quantum computing platform 1310 comprises a software and hardware platform which comprises various software layers that are configured to perform various functions, including, but not limited to, generating and implementing various quantum applications using suitable quantum programming languages, configuring and implementing various quantum gate operations, compiling quantum programs into a quantum assembly language, implementing and utilizing a suitable quantum instruction set architecture (ISA), etc. In addition, the quantum computing platform 1310 comprises a hardware architecture of processors, memory, etc., which is configured to control the execution of quantum applications, and interface with the control system 1320 to (i) generate digital control signals that are converted to analog microwave control signals by the control system 1320, to control operations of the quantum processor 1330 when executing a given quantum application, and (ii) to obtain and process digital signals received from the control system 1320, which represent the processing results generated by the quantum processor 1330 when executing various gate operations for a given quantum application.

In some exemplary embodiments, the quantum computing platform 1310 of the quantum computing system 1300 may be implemented using any suitable computing system architecture which is configured to implement methods to support quantum computing operations by executing computer readable program instructions that are embodied on a computer program product which includes a computer readable storage medium (or media) having such computer readable program instructions thereon for causing a processor to perform control methods as discussed herein.

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A method, comprising:
forming a multilevel wiring structure by a process which comprises:
forming a first metallization layer comprising a superconducting metal in a surface of a first substrate;
bonding a second substrate to the first substrate, the second substrate comprising a monocrystalline dielectric material;
thinning the second substrate to form an interlayer dielectric layer which comprises the monocrystalline dielectric material; and
forming a second metallization layer comprising a superconducting metal in a surface of the interlayer dielectric layer, wherein the second metallization layer is connected to the first metallization layer by at least one interlayer via in the interlayer dielectric layer.

2. The method of claim 1, wherein bonding the second substrate to the first substrate comprises performing a substrate-to-metal bonding process to bond the monocrystalline dielectric material of the second substrate to the first metallization layer of the first substrate.

3. The method of claim 1, wherein bonding the second substrate to the first substrate comprises performing a substrate-to-substrate bonding process to bond the monocrystalline dielectric material of the second substrate to monocrystalline dielectric material of the first substrate.

4. The method of claim 1, wherein bonding the second substrate to the first substrate comprises performing a metal-to-metal bonding process to bond a third metallization layer of superconducting metallic material, which is formed in a surface of the second substrate, to the first metallization layer of superconducting metallic material of the first substrate.

5. The method of claim 1, wherein thinning the second substrate to form the interlayer dielectric layer comprises:
etching the second substrate down to an etch stop layer; and
removing the etch stop layer selective to the monocrystalline dielectric material of the second substrate to form the interlayer dielectric layer which comprises a remaining portion of the second substrate after removing etch stop layer.

6. The method of claim 1, wherein:
the second substrate comprises the at least one interlayer via; and
thinning the second substrate to form the interlayer dielectric layer comprises performing a via reveal etch process to etch the second substrate to reveal an end portion of the at least one interlayer via.

7. The method of claim 1, wherein the first substrate and the second substrate are formed of a monocrystalline semiconductor material.

8. A device, comprising:
a substrate; and
a multilevel wiring structure disposed on a first surface of the substrate, and comprising a plurality of layers, wherein the plurality of layers comprises:
a first metallization layer and a second metallization layer, each comprising a superconducting metal; and
an interlayer dielectric layer disposed between the first metallization layer and the second metallization layer, the interlayer dielectric layer comprising a monocrystalline dielectric material.

9. The device of claim 8, wherein the multilevel wiring structure further comprises at least one interlayer via comprising a superconducting metal disposed in the interlayer dielectric layer and connecting the first metallization layer and the second metallization layer.

10. The device of claim 8, wherein the substrate and the interlayer dielectric layer are formed of a monocrystalline semiconductor material.

11. The device of claim 8, wherein the interlayer dielectric layer is formed of a monocrystalline oxide material.

12. The device of claim 8, further comprising:
at least one superconducting quantum bit disposed on a second surface of the substrate, opposite the first surface; and
at least one through-substrate via disposed in the substrate and providing a connection between the at least one superconducting quantum bit and the multilevel wiring structure.

13. The device of claim 8, wherein the plurality of layers of the multilevel wiring structure comprises at least one interlayer dielectric layer which comprises at least one superconducting quantum bit disposed thereon.

14. The device of claim 13, wherein the plurality of layers of the multilevel wiring structure comprises at least one metallization layer which comprises at least one readout resonator that is capacitively coupled to the at least one superconducting quantum bit.

15. The device of claim 8, wherein:
the plurality of layers of the multilevel wiring structure comprises at least one interlayer dielectric layer which comprises a first superconducting quantum bit and a second superconducting quantum bit; and
the multilevel wiring structure comprises at least one coupling bus that couples the first superconducting quantum bit and the second superconducting quantum bit.

16. A device, comprising:
a multilevel wiring structure comprising a plurality of metallization layers comprised of superconducting metal, and a plurality of interlayer dielectric layers comprised of monocrystalline dielectric material, each interlayer dielectric layer comprising interlayer vias comprised of superconducting metal to connect the metallization layers;
a plurality of superconducting quantum bits disposed on at least one interlayer dielectric layer of the multilevel wiring structure; and
a plurality of signal transmission lines which are comprised of portions of the metallization layers and the interlayer vias of the multilevel wiring structure, and which are configured to route signals to and from the superconducting quantum bits.

17. The device of claim 16, further comprising a plurality of coupling buses which are comprised of portions of the metallization layers and the interlayer vias of the multilevel wiring structure, each coupling bus configured to couple at least two superconducting quantum bits of the plurality of superconducting quantum bits.

18. The device of claim 16, further comprising a plurality of readout resonators which are comprised of portions of the metallization layers and the interlayer vias of the multilevel wiring structure, each readout resonator coupled to a given superconducting quantum bit of the plurality of superconducting quantum bits.

19. The device of claim 16, further comprising a second multilevel wiring structure, which is connected to the multilevel wiring structure with solder bump connections, the second multilevel wiring structure comprising a second plurality of metallization layers comprised of superconducting metal, and a second plurality of interlayer dielectric layers comprised of monocrystalline dielectric material, each interlayer dielectric layer of the second plurality of interlayer dielectric layers comprising interlayer vias comprised of superconducting metal to connect metallization layers of the second plurality of metallization layers.

20. A device, comprising:
a substrate comprising a first metallization layer which is comprised of a superconducting metal disposed in a surface of a first substrate;
an interlayer dielectric layer which comprises: a first surface disposed on the first metallization layer; a second metallization layer which is comprised of a superconducting metal and disposed on a second surface of the interlayer dielectric layer, opposite the first surface; and one or more interlayer vias which provide connections between the first metallization layer and the second metallization layer; and
a superconducting quantum bit comprising at least one Josephson junction and a superconducting capacitor coupled to the at least one Josephson junction;
wherein the at least one Josephson junction is disposed on the second surface of the interlayer dielectric layer; and
wherein the superconducting capacitor comprises patterned features of the first metallization layer and the second metallization layer.

21. The device of claim 20, wherein the patterned features of the superconducting capacitor comprise:
a first capacitor electrode and a second capacitor electrode, which are features of the second metallization layer; and
a ground plane, which is a feature of the first metallization layer, and disposed in alignment with the first capacitor electrode and the second capacitor electrode.

22. The device of claim 20, wherein the patterned features of the superconducting capacitor comprise:
a first capacitor electrode and a second capacitor electrode, which are features of the first metallization layer; and
a first contact pad and a second contact pad, which are features of the second metallization layer, wherein the first contact pad is connected to the first capacitor electrode by a first interlayer via in the interlayer dielectric layer, and the second contact pad is connected to the second capacitor electrode by a second interlayer via in the interlayer dielectric layer.

23. The device of claim 20, wherein the patterned features of the superconducting capacitor comprise:
a first capacitor electrode which is a feature of the first metallization layer;
a second capacitor electrode and a contact pad, which are features of the second metallization layer;
wherein the first capacitor electrode and the second capacitor electrode are disposed in alignment with each other to provide a parallel plate capacitor, and which are separated by a distance that corresponds to a thickness of the interlayer dielectric layer;
wherein the contact pad is connected to a first terminal of the Josephson junction and to the first capacitor electrode by an interlayer via in the interlayer dielectric layer; and
wherein the second capacitor electrode is connected to a second terminal of the Josephson junction.

24. A method, comprising:
forming a first metallization layer comprising a superconducting metal in a surface of a first substrate;
bonding a second substrate to the first substrate, the second substrate comprising a monocrystalline dielectric material;
thinning the second substrate to form an interlayer dielectric layer which comprises the monocrystalline dielectric material; and
forming a second metallization layer comprising a superconducting metal in a surface of the interlayer dielectric layer, wherein the second metallization layer is connected to the first metallization layer by one or more interlayer vias in the interlayer dielectric layer; and
forming at least one Josephson junction of a superconducting quantum bit on the surface of the interlayer dielectric layer;
wherein the first metallization layer and second metallization layer each comprise one or more patterned features of a superconducting capacitor of the superconducting quantum bit, which is coupled to the at least one Josephson junction.

25. The method of claim 24, wherein the monocrystalline dielectric material comprises a monocrystalline semiconductor material.
